(19) United States
(12) Patent Application Publication
(10) Pub. No.: US 2013/0114355 A1
(43) Pub. Date: May 9, 2013

(54) METHOD FOR ADJUSTING VOLTAGE CHARACTERISTICS OF SEMICONDUCTOR MEMORY ELEMENT, METHOD FOR ADJUSTING VOLTAGE CHARACTERISTICS OF SEMICONDUCTOR MEMORY DEVICE, CHARGE PUMP AND METHOD FOR ADJUSTING VOLTAGE OF CHARGE PUMP

(71) Applicants: Ken Takeuchi, Tokyo (JP); Kosuke Miyaji, Tokyo (JP); Shuhei Tanakamaru, Tokyo (JP); Kentaro Honda, Tokyo (JP)

(72) Inventors: Ken Takeuchi, Tokyo (JP); Kosuke Miyaji, Tokyo (JP); Shuhei Tanakamaru, Tokyo (JP); Kentaro Honda, Tokyo (JP)

(73) Assignee: SEMICONDUCTOR TECHNOLOGY ACADEMIC RESEARCH CENTER, Yokohama-shi, Kanagawa (JP)

(21) Appl. No.: 13/699,158

(22) PCT Filed: May 23, 2011
(86) PCT No.: PCT/JP2011/061761

§ 371 Date: Dec. 21, 2012

(30) Foreign Application Priority Data
May 24, 2010 (JP) 2010-118100

(51) Int. Cl. G11C 5/14; G11C 7/10; G05F 1/10

(52) U.S. Cl. CPC G11C 5/14; G05F 1/10; G11C 7/1096
USPC 365/189.16; 365/226; 327/536

(57) ABSTRACT

Voltages are applied to supply voltage application points of memory cells of an SRAM, a semiconductor substrate, a word line and bit lines so that voltage Vdd takes value V1, substrate voltage Vsub becomes 0 V, word line voltage Vw1 takes value V1, bit line voltage Vbll becomes 0 V, and bit line voltage Vblr takes value V1, the voltage difference between the word line and one of the bit lines is forced to be equal to a voltage difference V1h higher than a normal voltage difference V1 and the voltage difference between the word line and the other bit line is forced to be equal the normal voltage difference V1 lower than the voltage V1h to inject electrons into an insulating layer near a diffusion layer connected to an output terminal of an inverter constituting the memory cell. This can improve the operating characteristics of the memory cell.

### TECHNICAL FIELD

The present invention relates to a method for adjusting voltage characteristics of a semiconductor element, a method for adjusting voltage characteristics of a semiconductor memory device, and a charge pump and a method for adjusting voltage characteristics of a charge pump.

### BACKGROUND ART

A method for adjusting voltage characteristics of semiconductor memory devices of this type has been proposed in the past in which two halo regions having different peak impurity concentrations are formed between the source and drain of an insulted gate transistor making up a semiconductor memory device. A semiconductor memory device has been proposed in which this method is applied to a semiconductor device which an SRAM (Static Random Access Memory) cell having two inverters forming a latch and two access transistors, each of whose source or drain is connected to the output of the two inverters (see Non Patent Literature 1, for example). Two halo regions having different peak impurity concentrations are formed in the region between the source and drain of the access transistor, the source or drain adjacent to the halo region that has a higher peak impurity concentration is connected to the output of the inverter and the source or drain adjacent to the halo region that has a lower peak impurity concentration is connected to a bit line. This can facilitate inversion of data and can improve writability because when data that is the inverse of data stored in the latch is to be written, the threshold voltage of one of the two access transistors that is connected to the bit line to which a lower voltage is applied is lower than the threshold voltage of the other access transistor that is connected to the bit line to which a higher voltage is applied. A semiconductor memory device has been proposed, which is a charge pump in which multiple stages of transistors are connected in series by connecting the source of a transistor having a connection terminal to which its gate and drain are connected to the connection terminal of an adjacent transistor, and a supply voltage input into the connection terminal of the transistor at the first stage is increased at each transistor while applying a clock signal to the connection terminal through a capacitor and is output through the output terminal connected to the source of the transistor at the last stage (see Non Patent Literature 2, for example).

### PRIOR ART DOCUMENT

Non Patent Literature 1: Jae-Joon Kim, Aditya

Bansal, Rahul Rao, Shih-Hsien Lo and Ching-Te Chuang, “Relaxing Conflict Between Read Stability and Writability in 6T SRAM Cell Using Asymmetric Transistors”, IEEE ELECTRON DEVICE LETTERS, VOL. 30, NO. 8, AUGUST 2009, pp. 852-854

Non Patent Literature 2: Shinji Noda, Teruyoshi Hatanaka, Mitue Takahashi, Shigeki Sakai and Ken Takeuchi, “A 1.2V Operation 2.43 Times Higher Power Efficiency Adaptive Charge Pump Circuit with Optimized Vth at Each Pump Stage for Ferroelectric(Fe)-NAND Flash Memories”, Extended Abstract of the 2009 International Conference on Solid State Devices and Materials, Sendai, 2009, pp. 162-163

### SUMMARY OF INVENTION

However, since the voltage characteristics adjusting method described above requires formation of the halo regions, application of the voltage characteristics adjusting method to an SRAM or a charge pump requires additional processes such as an impurity doping process in manufacturing, which adds the complexity to the manufacturing process. Therefore, it is desirable to employ a simpler method for adjusting the voltage characteristics of SRAMs and charge pumps to improve the operating characteristics.

A principal object of the method for adjusting voltage characteristics of a semiconductor memory element and the method for adjusting voltage characteristics of a semiconductor memory device of the present invention and the charge pump and the method for adjusting the voltage of the charge pump of the present invention is to improve operating characteristics in a simpler way.

In order to achieve the principal object, the method for adjusting the voltage characteristics of a semiconductor memory element, the method for adjusting the voltage characteristics of a semiconductor memory device and the charge pump and the method for adjusting the voltage of the charge pump adopt the following means.

According to one aspect, the present invention is directed to a method for adjusting voltage characteristics of a semiconductor memory element formed on a semiconductor substrate. The semiconductor memory element including a first inverter having a first input terminal and a first output terminal, a second inverter having a second input terminal connected to the first output terminal and a second output terminal connected to the first input terminal, a first pass gate transistor having a first gate insulating layer having a predetermined insulation performance, and a second pass gate transistor having a second gate insulating layer having a predetermined insulation performance, a gate of the first pass gate transistor being connected to a word line, one of a source and a drain of the first pass gate transistor being connected to the first output terminal of the first inverter, the other of the source and the drain of the first pass gate transistor being connected to one of two bit lines, a gate of the second pass gate transistor being connected to the word line, one of a source and a drain of the second pass gate transistor being connected to the output terminal of the second inverter, the other of the source and the drain of the second pass gate transistor being connected to the other of the two bit lines. The method includes: a voltage adjusting step of adjusting a voltage to be applied to a supply voltage application point and a voltage to be applied to the two bit lines so that a voltage difference between a supply voltage application point to which a supply voltage is to be applied when the semiconductor memory element is caused to perform a normal operation and the two bit lines becomes equal to a predetermined voltage difference greater than a voltage difference between the supply voltage application point and the two bit lines when the semiconductor memory element is caused to perform the normal operation.

A method for adjusting the voltage characteristics of a semiconductor memory element according to the present invention adjusts a voltage to be applied to a supply voltage application point and a voltage to be applied to the two bit lines so that a voltage difference between a supply voltage application point to which a supply voltage is to be applied when the semiconductor memory element is caused to perform a normal operation and the two bit lines becomes equal to a predetermined voltage difference greater than a voltage difference between the supply voltage application point and the two bit lines when the semiconductor memory element is caused to perform the normal operation. This can increase the threshold voltage of the first or second pass gate transistors when the voltage of the connected bit line is higher than the voltage at the connected output terminal to a level higher than the threshold voltage when the voltage of the connected bit line is lower than the voltage at the connected output terminal. Once the voltage adjusting step is performed, this state of the pass gate transistor is maintained after the application of the voltages to the supply voltage application point and the two bit lines is halted. Therefore, operating characteristics of the semiconductor memory element can be improved, such as the readout characteristics for reading data stored in the semiconductor memory element through the two bit lines and the write characteristics for writing data into the semiconductor memory element through the two bit lines.

The method for adjusting the voltage of a semiconductor memory element according to the present invention may include, before the voltage adjusting step, a write step of applying a normal-operation on-control voltage to the word line while a first bit voltage out of the first bit voltage and a second bit voltage is being applied to one of the two bit lines and the second bit voltage lower than the first bit voltage is being applied to the other of the two bit lines, the first bit voltage being a voltage to be applied to the bit lines when the semiconductor memory element is caused to perform a normal operation, the normal-operation on-control voltage being a voltage turning on the first pass gate transistor and the second pass gate transistor when the semiconductor memory element is caused to perform the normal operation. This enables the voltage adjustment step to be performed while the voltage at the first output terminal of the first inverter and the voltage at the second output terminal of the second inverter are at levels according to the voltage of the bit lines. Accordingly, the operating characteristics of the semiconductor memory element can be improved more properly.

The method for adjusting the voltage characteristics of a semiconductor memory element according to the present invention may include, before the voltage adjusting step, a low supply voltage applying step of applying a predetermined low voltage to the supply voltage application point while a normal-operation off-control voltage is being applied to the word line and a normal-operation substrate voltage is being applied to the semiconductor substrate, the normal-operation off-control voltage being a voltage turning off the first pass gate transistor and the second pass gate transistor when the semiconductor memory element is caused to perform a normal operation, the normal-operation substrate voltage being a voltage to be applied to the semiconductor substrate when the semiconductor memory element is cause to perform the normal operation, the predetermined low voltage being a voltage lower than a supply voltage to be applied to the supply voltage application point when the semiconductor memory element is caused to perform the normal operation. This can force the voltage at the first output terminal of the first inverter and the voltage at the first output terminal of the second inverter to be voltage levels reflecting a difference in current driving performance between the first and second inverters before the voltage adjusting step is performed. Accordingly, the operating characteristics of the semiconductor memory element can be improved more properly. In this case, the method may also include, between the low supply voltage applying step and the voltage adjusting step, a read step of applying a normal-operation on-control voltage to the word line while the two bit lines are placed in an electrically floating state and the normal-operation substrate voltage is being applied to the semiconductor substrate, the normal-operation on-control voltage being a voltage turning on the first pass gate transistor and the second pass gate transistor when the semiconductor memory element is caused to perform a normal operation. This can force the voltage at the first output terminal of the first inverter and the voltage at the first output terminal of the second inverter to be voltage levels reflecting differences in current driving performance between the first and second inverters and the first and second pass gate transistors before the voltage adjusting step is performed. Accordingly, the operating characteristics of the semiconductor memory element can be improved more properly.

The voltage adjusting step of the method for adjusting the voltage of a semiconductor memory element according to the present invention may be the step of adjusting a voltage to be applied to the supply voltage application point, a voltage to be applied to the word line and a voltage to be applied to the two bit lines so that a voltage difference between the supply voltage application point and the two bit lines becomes equal to the predetermined voltage difference and a voltage difference between the word line and the two bit lines becomes equal to a predetermined low voltage difference smaller than the predetermined voltage difference. In this case, the voltage adjusting step may be the step of applying a normal-operation on-control voltage to the word line, a second bit voltage out of a first bit voltage and the second bit voltage to the two bit lines, a predetermined high supply voltage to the supply voltage application point, the first and second bit voltages are voltages to be applied to the bit lines when the semiconductor memory element is caused to perform a normal operation, the second bit voltage being lower than the first bit voltage, the predetermined high supply voltage being a voltage higher than a supply voltage to be applied to the supply voltage application point when the semiconductor memory element is caused to perform the normal operation and higher than the normal-operation on-control voltage. This can increase the threshold voltage when the voltage of the connected bit line is higher than the voltage at the connected output terminal to a voltage level higher than the threshold voltage when the voltage of the connected bit line is lower than the voltage at the output terminal for the first or second pass gate transistor that is connected to the first output terminal of the first inverter or the second output terminal of the second inverter, whichever has a higher voltage. Accordingly, the operating characteristics of the semiconductor memory element can be improved. In this case, the voltage adjusting step may be the step of applying the normal operation on-control voltage to the word line, the second bit voltage to the two bit lines, and the predetermined high supply voltage to the supply voltage application point in a state where a voltage to be applied to the semiconductor substrate has been adjusted so that a voltage applied to the semiconductor substrate is lower than a normal substrate voltage to be applied to the semiconductor substrate when the semiconductor memory device is caused to perform the normal operation. This can increase the voltage at the first output terminal of the first inverter or the voltage at the second output terminal of the second inverter, whichever is higher, to a voltage level higher than when a normal substrate voltage is applied to the semiconductor substrate. Accordingly, the threshold voltage when the voltage of the connected bit line is higher than the voltage at the connected output terminal can be increased and the operating characteristics can be improved more properly.

Furthermore, the method for adjusting the voltage of a semiconductor memory element according to the present invention may include the step of adjusting a voltage to be applied to the supply voltage application point and a voltage to be applied to the two bit lines so that a voltage difference between the supply voltage application point and the two bit lines becomes equal to the predetermined voltage difference and a voltage difference between the word line and the two bit lines becomes equal to a predetermined high voltage difference greater than the predetermined voltage difference. In this case, the voltage adjusting step may be the step of applying a predetermined off voltage to the word line, applying a predetermined high bit voltage to the two bit lines, and applying a predetermined low supply voltage to the supply voltage application point, the predetermined off-voltage being lower than a normal-operation off-control voltage turning off the first pass gate transistor and the second pass gate transistor when the semiconductor memory element is caused to perform a normal operation, the predetermined high bit voltage being a higher than a first bit voltage out of the first bit voltage and a second bit voltage to be applied to the bit lines when the semiconductor memory element is caused to perform the normal operation, the second bit voltage being lower than the first bit voltage, the predetermined low supply voltage being lower than a supply voltage to be applied to the supply voltage application point when the semiconductor memory element is caused to perform the normal operation. This can increase the threshold voltage when the voltage of the connected bit line is higher than the voltage at the output terminal to a level higher than the threshold voltage when the voltage of the connected bit line is lower than the voltage at the connected output terminal for the first or second pass gate transistor connected to the first output terminal of the first inverter or the second output terminal of the second inverter, whichever has a lower voltage. Accordingly, the operating characteristics of the semiconductor memory element can be improved.

According to another aspect, the present invention is directed to a charge pump including a multi-stage transistor circuit, a capacitor circuit, an input signal supply circuit, and a control circuit, the multi-stage transistor circuit having a first input terminal, a second input terminal, a third input terminal, and an output terminal and including n transistors connected in series (n is an integer greater than or equal to 2), each of the n transistors having a connection terminal, a gate of each of the n transistors being formed on an insulating layer having a predetermined insulation performance, one of a source and a drain of each of the transistors and the gate being connected to the connection terminal, the source of each of the transistors being connected to the connection terminal of an adjacent transistor, the connection terminal of the transistor at the first stage among the n transistors being connected to the first input terminal, the source of the transistor at the last stage among the n transistors being connected to the output terminal, the capacitor circuit including (n−1) capacitors, one end of each of the capacitors being connected to the connection terminal of (n−1) transistors among the n transistors of the multi-stage transistor circuit excluding the transistor at the first stage, the other end of each of adjacent capacitors that is different from the one end being alternately connected to the second input terminal or the third terminal, the input signal supply circuit being capable of supplying a voltage or a clock signal to the first input terminal, the second input terminal and the third input terminal, the control circuit controlling the input signal supply circuit so that the clock signal is input into the second input terminal and an inverted clock signal that is the inverse of the clock signal is input into the third input terminal while a supply voltage is being supplied to the first input terminal when the charge pump is in a normal operation. The charge pump includes: a control voltage supply circuit having n control terminals and supplying a voltage to each of the control terminals; and n switching elements turning on and off supply of a voltage from the n control terminals to the connection terminals and gates of n transistors of the multi-stage transistor circuit; wherein the control circuit controls the input signal supply circuit, the control voltage supply circuit, and the n switching elements so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching in the on state and a predetermined high voltage higher than the predetermined low voltage is applied to the other of the control terminals connected to the two switching elements in the on state.

In the charge pump of the present invention, the input signal supply circuit is controlled so that the clock signal is input into the second input terminal and an inverted clock signal that is the inverse of the clock signal is input into the third input terminal while a supply voltage is being supplied to the first input terminal when the charge pump is in a normal operation. This can increase the supply voltage input into the first input terminal and output the increased supply voltage through the output terminal. The input signal supply circuit, the control voltage supply circuit, and the n switching elements are controlled so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching in the on state and a predetermined high voltage higher than the predetermined low voltage is applied to the other of the control terminals connected to the two switching elements in the on state. This can decrease the threshold voltage when the voltage at the connection terminal of the transistor nearer to the last stage is higher than the connection terminal of the transistor nearer to the first stage to a level lower than the threshold voltage when the voltage at the connection terminal of the transistor nearer to the last stage is lower than the voltage at the connection terminal of the transistor nearer to the first stage, for the transistor at the first stage of the multistage transistor circuit out of two transistors connected to two switching elements e in the on stage. Since this state of the transistors is maintained after voltage supply to the first, second and third input terminals is halted, the voltage rising efficiency, that is, the operating characteristics, of the transistors making up the multistage transistor circuit when a voltage at the first input terminal is increased and the increased voltage is output through the output terminal.

In the charge pump according to the present invention, the control circuit may be a circuit that controls the input signal supply circuit, the n switching elements and the control voltage supply circuit so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching elements in the on state that is nearer to the transistor at the first stage of the multi-stage transistor circuit and a predetermined high voltage higher than the predetermined low voltage is applied to the other of the control terminals connected to the two switching elements in the on state that is nearer to the transistor at the last stage of the multi-stage transistor circuit. Also, the control circuit may be a circuit that controls the input signal supply circuit, the n switching elements and the control voltage supply circuit so that, while a predetermined low voltage is being input in the first input terminal, the second input terminal and the third input terminal and adjacent two of the n switching elements are in the on state and the other switching elements are in the off state, a predetermined high voltage higher than the predetermined low voltage is applied to one of the control terminals connected to the two switching elements in the on state that is nearer to the transistor at the first stage of the multi-stage transistor circuit and a voltage lower than or equal to the predetermined low voltage is applied to the other of the two control terminals connected to the two switching elements in the on state that is nearer to the last stage of the multi-state transistor circuit.

According to one aspect, the present invention is directed to the voltage characteristics adjusting method for adjusting voltage characteristics of a charge pump including a multi-stage transistor circuit, a capacitor circuit, an input signal supply circuit, a control voltage supply circuit and n switching elements, the multi-stage transistor circuit having a first input terminal, a second input terminal, a third input terminal, and an output terminal and including n transistors connected in series (n is an integer greater than or equal to 2), each of the n transistors having a connection terminal, a gate of each of the n transistors being formed on an insulating layer having a predetermined insulation performance, one of a source and a drain of each of the transistors and the gate being connected to the connection terminal, the source of each of the transistors being connected to the connection terminal of an adjacent transistor, the connection terminal of the transistor at the first stage among the n transistors being connected to the first input terminal, the source of the transistor at the last stage among the n transistors being connected to the output terminal, the capacitor circuit includes (n−1) capacitors, one end of each of the capacitors being connected to the connection terminal of (n−1) transistors among the n transistors of the multi-stage transistor circuit excluding the transistor at the first stage, the other end of each of adjacent capacitors that is different from the one end being alternately connected to the second input terminal or the third terminal, the input signal supply circuit being capable of supplying a voltage or a clock signal to the first input terminal, the second input terminal and the third input terminal, the control voltage supply circuit having n control terminals and supplying a voltage to each of the control terminals, the n switching elements turning on and off supply of a voltage from the n control terminals to the connection terminals and the gate of the n transistors of the multi-stage transistor circuit, the charge pump controls the input signal supply circuit and the n switching elements so that the clock signal is input into the second input terminal and an inverted clock signal that is the inverse of the clock signal is input into the third input terminal while the n switching elements are turned off and a supply voltage is being supplied to the first input terminal when the charge pump is in a normal operation, wherein the method controls the input signal supply circuit, the control voltage supply circuit and the n switching elements so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching in the on state and a predetermined high voltage higher than the predetermined low voltage is applied to the other of the control terminals connected to the two switching elements in the on state.

The method for adjusting the voltage characteristics of a charge pump according to the present invention controls the input signal supply circuit, the control voltage supply circuit and the n switching elements so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching in the on state and a predetermined high voltage higher than the predetermined low voltage is applied to the other of the control terminals connected to the two switching elements in the on state. This can decrease the threshold voltage when the voltage at the connection terminal of the transistor nearer to the last stage is higher than the connection terminal of the transistor nearer to the first stage to a level lower than the threshold voltage when the voltage at the connection terminal of the transistor nearer to the last stage is lower than the voltage at the connection terminal of the transistor nearer to the first stage, for the transistor at the first stage of the multistage transistor circuit out of two transistors connected to two switching elements in the on stage. Since this state of the transistors is maintained after voltage supply to the first, second and third input terminals is halted, the voltage rising efficiency, that is, the operating characteristics, of the transistors making up the multistage transistor circuit when a voltage at the first input terminal is increased and the increased voltage is output through the output terminal.

According to another aspect, a method for adjusting voltage characteristics of a semiconductor memory device including n semiconductor memory elements (n is an integer greater than or equal to 2) each including a first inverter having a first input terminal and a first output terminal, a second inverter having a second input terminal connected to the first output terminal and a second output terminal connected to the first input terminal, a first pass gate transistor having a first gate insulating layer having a predetermining insulating performance, and a second pass gate transistor having a second gate insulating layer having a predetermined insulating performance, n word lines connected to the gate of the first pass gate transistor and the gate of the second pass gate transistor of each of the n semiconductor memory elements, a first bit line connected to one of the source and the drain of the first pass gate transistor, and a second bit line connected to one of the source and the drain of the second pass gate transistor, the other of the source and drain of the first pass gate transistor being connected to the first output terminal of the first inverter, the other of the source and the drain of the second pass gate transistor being connected to the output terminal of the second inverter. The method includes: a first step of performing a write operation on at least two of the n semiconductor memory elements, the write operation adjusting a voltage to be applied to a supply voltage application point of each of the semiconductor memory element, a voltage to be applied to the first bit line, a voltage to be applied to the second bit line, and a voltage to be applied to the word line, so that a voltage difference between the supply voltage application point to which a supply voltage is to be applied when the semiconductor memory element is cause to perform a normal operation and a word line connected to the first pass gate transistor and the second pass gate transistor of the semiconductor memory element and a voltage difference between the first bit line and the second bit line become equal to a voltage difference between the supply voltage application point and the word line and a voltage difference between the two bit lines when data is normally written into the semiconductor memory element; after the first step, a second step of performing a low supply voltage read operation on the at least two semiconductor memory elements, the low supply voltage read operation adjusting a voltage to be applied to the supply voltage application point of the semiconductor memory element and a voltage to be applied to the word line so that a normal on voltage which is a voltage turning on the first pass gate transistor and the second pass gate transistor of the semiconductor memory element is applied to the word line while a voltage lower than a normal supply voltage which is a voltage to be applied to the supply voltage application point when the semiconductor memory element is caused to perform a normal operation is being applied to the supply voltage application point; and after the second step, a third step of adjusting a voltage to be applied to the supply voltage application point of each of the at least two semiconductor memory elements and a voltage to be applied to a word line connected to the at least two semiconductor memory elements so that a voltage higher than or equal to the normal on voltage and lower than the normal supply voltage is applied to the word line connected to the first pass gate transistor and the second pass gate transistor of the at least two semiconductor memory elements while a voltage higher than the normal supply voltage is being applied to the supply voltage application point of each of the at least two semiconductor memory elements.

A method for adjusting voltage characteristics of a semiconductor memory device according to the present invention performs a write operation on at least two of the n semiconductor memory elements. The write operation adjusts a voltage to be applied to a supply voltage application point of each of the semiconductor memory element, a voltage to be applied to the first bit line, a voltage to be applied to the second bit line, and a voltage to be applied to the word line, so that a voltage difference between the supply voltage application point to which a supply voltage is to be applied when the semiconductor memory element is cause to perform a normal operation and a word line connected to the first pass gate transistor and the second pass gate transistor of the semiconductor memory element and a voltage difference between the first bit line and the second bit line become equal to a voltage difference between the supply voltage application point and the word line and a voltage difference between the two bit lines when data is normally written into the semiconductor memory element. This can force the voltage at the first output terminal of the first inverter or the second output terminal of the second inverter to be equivalent to the voltage to be applied to the first bit line and the voltage to be applied to the second bit line for at least two of the n semiconductor memory elements. After the first step is completed, a low supply voltage read operation is performed on the at least two semiconductor memory elements. The low supply voltage read operation adjusts a voltage to be applied to the supply voltage application point of the semiconductor memory element and a voltage to be applied to the word line so that a normal on voltage which is a voltage turning on the first pass gate transistor and the second pass gate transistor of the semiconductor memory element is applied to the word line while a voltage lower than a normal supply voltage which is a voltage to be applied to the supply voltage application point when the semiconductor memory element is caused to perform a normal operation is being applied to the supply voltage application point. If the current driving performance of the first pass gate transistor and the second pass gate transistor is higher than the current driving performance of the first inverter and the second inverter of a semiconductor memory element, that is, if the threshold voltages of the first pass gate transistor and the second pass gate transistor are lower, execution of the second step changes the voltage at the first output terminal of the first inverter and the voltage at the second output terminal of the second inverter from the voltage at those terminals after the execution of the first step, that is, data stored is inverted. Executing the first and second steps in sequence enables only data stored in one of the at least two semiconductor memory elements that has the pass gate transistor having a lower threshold voltage to be inverted. Furthermore, after the execution of the second step is performed, a voltage to be applied to the supply voltage application point of each of the at least two semiconductor memory elements and a voltage to be applied to a word line connected to the at least two semiconductor memory elements are adjusted so that a voltage higher than or equal to the normal on voltage and lower than the normal supply voltage is applied to the word line connected to the first pass gate transistor and the second pass gate transistor of the at least two semiconductor memory elements while a voltage higher than the normal supply voltage is being applied to the supply voltage application point of each of the at least two semiconductor memory elements. This enables injection of electrons into the insulting layer of the pass gate transistor (the first pass gate transistor or the second pass gate transistor) connected to the first output terminal of the first inverter and the second output terminal of the second inverter, whichever has a higher voltage, of the semiconductor memory element storing inverted data to increase the threshold voltage. Consequently, the voltage characteristics of the semiconductor memory device can be improved.

In the method for adjusting voltage characteristics of a semiconductor memory device according to the present invention, the write operation of the first step may be the operation of adjusting a voltage to be applied to the supply voltage application point of the semiconductor memory element, a voltage to be applied to the first bit line, and a voltage to be applied to the second bit line so that a first bit voltage which is a voltage to be applied to the bit line when the semiconductor memory element is caused to perform a normal operation out of the first bit voltage and a second bit voltage lower than the first bit voltage is applied to one of the first and second bit lines and the second bit voltage to the other of the first and second bit lines while the normal supply voltage is being applied to the supply voltage application point and the normal on voltage is being applied to the word line. In this case, the method may include, after the third step, a fourth step of performing an after-third-step write operation on at least two of the n semiconductor memory elements, the after-third-step write operation adjusting a voltage to be applied to the supply voltage application point of each of the semiconductor memory elements, a voltage to be applied to the first bit line, a voltage to be applied to the second bit line, and a voltage to be applied to the word so that the first bit voltage is applied to the other of the first and second bit lines and the second bit voltage is applied to one of the first and second bit lines while the normal supply voltage is being applied to the supply voltage application point and the normal on voltage is being applied to the word line. The second and third steps may be performed after the fourth step. This enables injection of electrons into the insulating layer of any of first and second pass gate transistors that has a low threshold voltage to increase the threshold voltage. Consequently, the voltage characteristics of the semiconductor memory device can be improved.

In a method for adjusting voltage characteristics of a semiconductor memory device according to the present invention in a mode in which the first to fourth steps are performed, the first step may be the step of performing the write operation on the n semiconductor memory elements, the second step may be the step of performing the low voltage read operation on the n semiconductor memory elements, the third step may be the step of adjusting a voltage to be applied to the supply voltage application point of each of the n semiconductor memory elements and a voltage to be applied to the n word lines so that a voltage higher than or equal to the normal on voltage and the lower than the normal supply voltage is applied to the n word lines while a voltage higher than the normal supply voltage is being applied to the supply voltage application point of each of the n semiconductor memory elements, and the fourth step may be the step of performing the after-third-step write operation on the n semiconductor memory elements. This can increase the threshold voltage of a semiconductor memory element whose first or second pass gate transistor has a low threshold voltage among the n semiconductor memory elements. Consequently, the voltage characteristics of the semiconductor memory device can be improved.

### BRIEF DESCRIPTION OF DRAWINGS

FIG. 1 is a diagram schematically illustrating a configuration of an SRAM (Static Random Access Memory) 10 including a plurality of memory cells 12 whose voltage characteristics are to be adjusted by a voltage characteristic adjusting method of a first embodiment of the present invention;

FIG. 2 is a circuit diagram schematically illustrating a configuration of a memory cell 12;

FIG. 3 is a diagram illustrating an exemplary configuration of a transistor NL, NR and a pass gate transistor PGL, PGR;

FIG. 4 is a diagram illustrating an exemplary configuration of a transistor PL, PR;

FIG. 5 is a flowchart illustrating an example of a voltage characteristics adjusting process for adjusting the voltage characteristics of the SRAM 10;

FIG. 6 is a diagram illustrating a state of a pass gate transistor PGR in the processing at step S110;

FIG. 7 is a diagram illustrating the relationship among gate voltage Vg of a transistor with an insulating layer 22 injected with hot electrons, drain current Id flowing from the drain to the source, and threshold voltage;

FIG. 8 is a diagram illustrating the state of a memory cell 12 during a data read operation;

FIG. 9 is a diagram illustrating the state of the memory cell 12 during a data write operation;

FIG. 10 is a flowchart illustrating an example of a voltage characteristics adjusting process for adjusting the voltage characteristics of an SRAM 10 of a second embodiment;

FIG. 11 is a diagram illustrating the state of a pass gate transistor PGL in the processing at step S110B;

FIG. 12 is a diagram illustrating the relationship among gate voltage Vg of a transistor with an insulating layer 22 injected with holes, drain current Id, and threshold voltage;

FIG. 13 is a flowchart illustrating an example of a voltage characteristics adjusting process for adjusting the voltage characteristics of an SRAM 10 of a third embodiment;

FIG. 14 is a diagram schematically illustrating a configuration of an SRAM 210 of a variation;

FIG. 15 is a circuit diagram schematically illustrating a configuration of a memory cell 212 of the variation;

FIG. 16 is a diagram schematically illustrating a configuration of a charge pump 100 of an embodiment of the present invention;

FIG. 17 is a diagram illustrating an exemplary configuration of one of transistors Tr1 to Trn;

FIG. 18 is a diagram illustrating how the voltage characteristics of the charge pump 100 are adjusted;

FIG. 19 is a diagram illustrating the state of a transistor Tr2 during adjustment of voltage characteristics;

FIG. 20 is a diagram illustrating the relationship among gate voltage Vg of a transistor with an insulating layer 122 injected with holes, drain current Id flowing from the drain to the source, and threshold voltage;

FIG. 21 is a diagram illustrating the hole-injected transistor Tr2 at rising of a clock signal CLK;

FIG. 22 is a diagram illustrating the hole-injected transistor Tr2 at falling of the clock signal CLK;

FIG. 23 is a diagram illustrating the state of the transistor Tr2 during adjustment of voltage characteristics by a voltage characteristics adjusting method of a variation;

FIG. 24 is a diagram illustrating the relationship among gate voltage Vg of a transistor with an insulating layer 122 injected with hot electrons, drain current Id flowing from the drain to the source, and threshold voltage;

FIG. 25 is a diagram illustrating the electron-injected transistor Tr2 at rising of a clock signal CLK;

FIG. 26 is a diagram illustrating the electron-injected transistor Tr2 at falling of the clock signal CLK;

FIG. 27 is a diagram schematically illustrating a configuration of an SPAM 410 including a plurality of memory cells whose voltage characteristics are to be adjusted by a voltage characteristics adjusting method of a fourth embodiment of the present invention;

FIG. 28 is a diagram schematically illustrating a configuration of a subject part of the SRAM 410;

FIG. 29 is a flowchart illustrating an example of a voltage characteristics adjusting process for adjusting the voltage characteristics of the SRAM 410; and

FIG. 30 is a diagram illustrating bias conditions and an example of current flowing through the SRAM 410 during the processing at step S220.

### DESCRIPTION OF EMBODIMENTS

Modes for carrying out the present invention will be described with embodiments.

FIG. 1 is a diagram schematically illustrating a configuration of an SRAM (Statistic Random Access Memory) including a plurality of memory cells whose voltage characteristics are to be adjusted by a voltage characteristics adjusting method of a first embodiment of the present invention. The SRAM 10 includes a plurality of memory cells 12 connected to a plurality of word lines WL and a plurality of bit lines BLL, BLR arranged in a matrix, a row decoder 14 which selects a word line WL corresponding to a row address signal when the row address signal is provided, a column decoder 16 selecting a pair of bit lines BLL, BLR corresponding to a column address signal when the column address signal is provided, a plurality of sense amplifiers 18 amplifying signals output from memory cells 12 to bit lines BLL, BLR, and a column select circuit 19 connecting selected bit lines BLL, BLR to a data line, not depicted, to which data is input and output. The memory cells 12 arranged in a row are connected to the same word line WL and the memory cells 12 arranged in a column are connected to a pair of bit lines BLL, BLR.

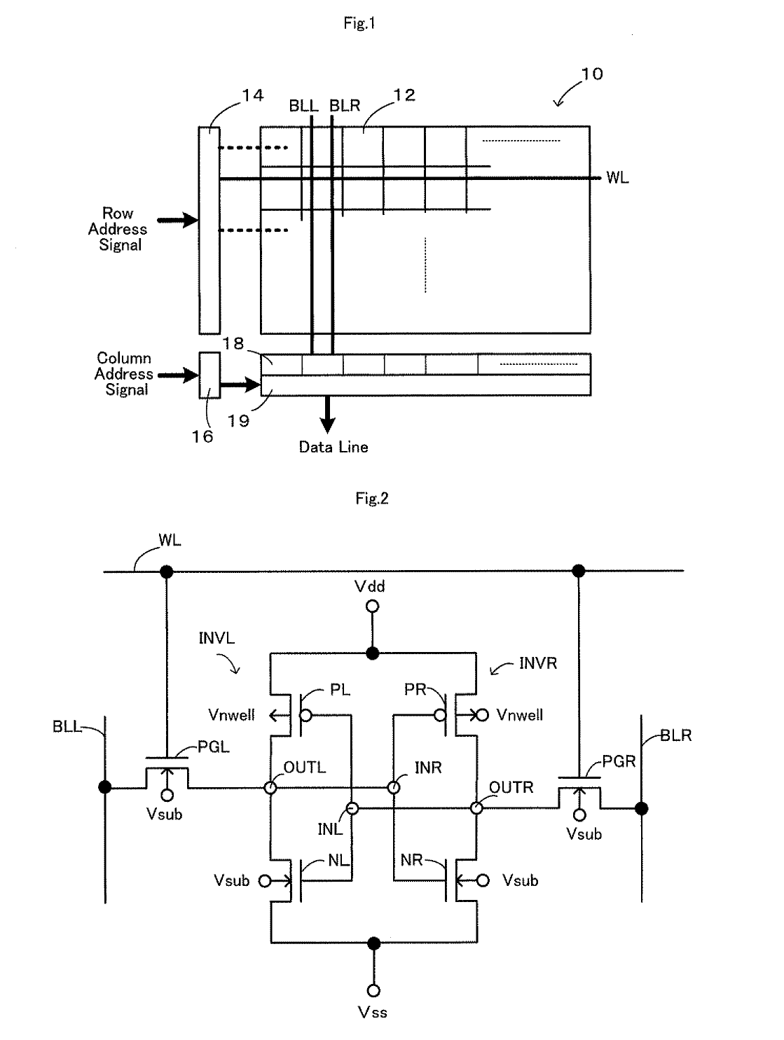

FIG. 2 is a circuit diagram schematically illustrating a configuration of a memory cell 12. The memory cell 12 includes an inverter INVL having a p-channel MOS transistor PL and an n-channel MOS transistor NL (hereinafter referred to as transistors PL, NL) the gates of which are connected to an input terminal INL and the drains of which are connected to an output terminal OUTL, an inverter INVR having a p-channel MOS transistor PR and an n-channel MOS transistor NR (hereinafter referred to as transistors PR, NR) the gates of which are connected to an input terminal INR and the drains of which are connected to an output terminal OUTR and having an input terminal INR connected to the output terminal OUTL of the inverter INVL and an output terminal OUTR connected to the input terminal INL of the inverter INVL, an n-channel MOS transistor PGL (hereinafter referred to as pass gate transistor PGL) which has a gate connected to a word line WL, electrically connects the output terminal OUTL to a bit line BLL when turning on, and electrically disconnects the output terminal OUTL from the bit line BLL when turning off, and an n-channel MOS transistor (hereinafter referred to as pass gate transistor PGR) which has a gate connected to the word line WL, electrically connects the output terminal OUTR to a bit line BLR when turning on, and electrically disconnects the output OUTR from the bit line BLR when turning off. The transistors PL, PR of the inverters INVL, INVR are connected to a supply voltage application point Vdd to which a supply voltage is applied when the sources are in a normal operation and the transistors NL, NR are connected to a ground voltage application point Vss to which a ground voltage Vss is applied when the sources are in a normal operation.

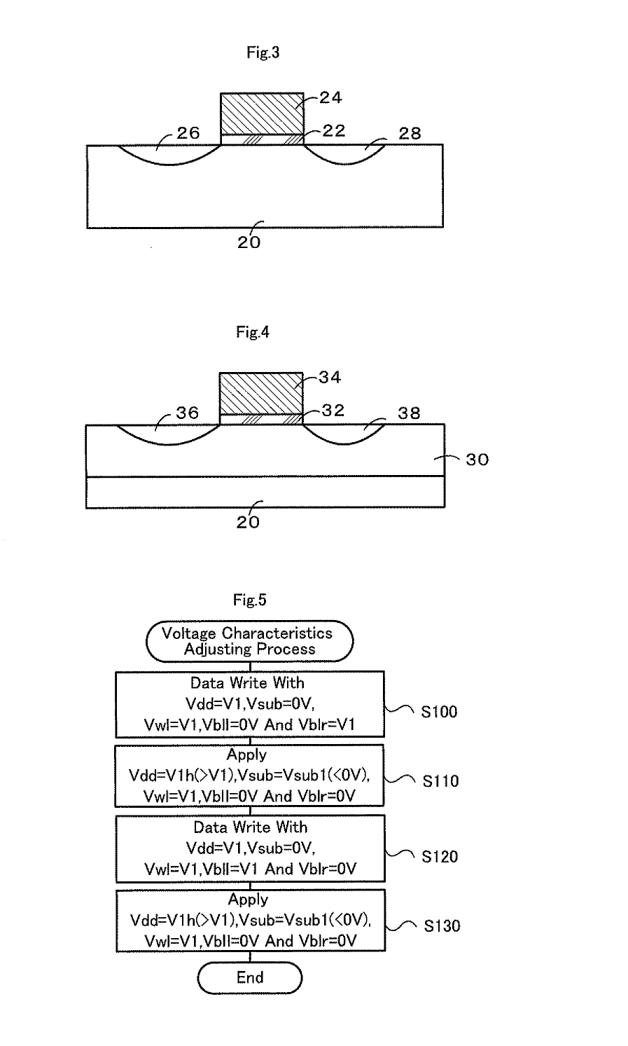

A structure of the transistors PL, PR, NL, NR, pass gate transistors PGL, PGR making up the inverters INVL, INVR will be described here. As illustrated in FIG. 3, each of the transistors NL, NR, and the pass gate transistors PGL, PGR are configured as a well-known n-channel MOS transistor which includes an insulating layer 22 formed of a material having a high insulation performance such as silicon dioxide (SiO₂) on a semiconductor substrate 20 made of a semiconductor material such as silicon (Si) controlled to p-conductivity type, a gate electrode 24 which is formed of a metallic material such as polysilicon on the insulating layer 22 and functions as a gate, and two diffusion layers 26, 28 of the n-conductivity type which are formed in the semiconductor substrate 20 on both sides of the lower portion of the insulating layer 22 of the semiconductor substrate 20 and function as a source or drain. As illustrated in FIG. 4, each of the transistors PL, PR is configured as a well-known p-channel MOS transistor which includes an insulating layer formed of a material having a high insulation performance such as a silicon dioxide (SiO₂) on a well 30 controlled to n-type conductivity formed on the semiconductor substrate 20, a gate electrode 34 which is formed of a metallic material such as polysilicon on the insulating layer 32 and functions as a gate, and diffusion layers 36, 38 of p-conductivity type which are formed in the well 30 on both sides of the lower portion of the insulating layer 32 of the well 30 and function as a source or drain. The transistors PL, PR, NL, NR and the pass gate transistors PGL, PGR are formed on the same semiconductor substrate 20 and the transistors PL, PR are isolated from the transistors NL, NR, the pass gate transistors. PGL, PGR by an insulator such as an oxide film, not shown, having a high insulation performance.

In the SRAM 10 thus configured, the well 30 is connected to the supply voltage application point Vdd. Voltages are applied to the supply voltage application point Vdd, the ground voltage application point Vss, and the semiconductor substrate 20 so that basically a voltage Vdd takes a value VI (for example 1.0 V), a ground voltage Vss is 0 V, and a substrate voltage Vsub is 0 V, where the voltage Vdd is the voltage applied to the supply voltage application point Vdd, the ground voltage Vss is the voltage applied to the ground voltage application point Vss, and the substrate voltage Vsub is the voltage applied to the semiconductor substrate 20. These voltages are applied to all of the memory cells 12 at once. While these voltages are applied to the supply voltage application point Vdd, the ground voltage application point Vss and the semiconductor substrate 20, each of the memory cells 12 functions as a bistable-state circuit in which when the voltage at the output terminal OUTL is high (hereinafter referred to as the H level) due to a data write operation, a data read operation or a data hold operation, the voltage at the output terminal OUTR is low (hereinafter referred to as the L level) whereas when the output terminal OUTL is at the L level, the output terminal OUTR is at the H level. Change of the voltage at the output terminal OUTL or OUTR from the H level to the L level or the L level to the H level will be referred to as “the level inverts”.

Specifically, a data write operation to the SRAM 10 is accomplished as follows. When signals such as a row address signal and a column address signal required for the operation are provided and the voltages of bit lines BLL, BLR (hereinafter referred to as bit line voltages Vbll, Vblr) are forced to values corresponding to data to be written, one word line WL is selected by the row decoder 14 on the basis of the row address signal, the voltage of the word line WL (hereinafter referred to as the word line voltage Vw1) takes a value V1, one pair of bit lines BLL, BLR are selected by the column decoder 16 on the basis of the input column address signal, and the voltages at the output terminals OUTL, OUTR of a memory cells 12 connected to the selected word line WL and bit lines BLL, BLR are changed to a voltage corresponding to the bit lines BLL, BLR. An operation to read data from the SRAM 10 is accomplished as follows. When signals such as a row address signal and a column address signal required for the operation are provided and bit lines BLL, BLR are placed in an electrically floating state while being precharged to a voltage Vdd (value V1) to be applied to the supply voltage application point Vdd, the voltage difference between the bit lines BLL, BLR caused according to the voltage difference between the output terminals OUTL, VR of a memory cell 12 connected to the word line WL and the bit lines BLL, BLR selected by the row decoder 14 and the column decoder 16 is read as data. A data hold operation is accomplished as follows. All of the word lines WL and bit lines BLL, BLR are deselected and the pass gate transistors PGL, PGR turn off to hold the voltages at the output terminals OUTL, OUTR of the memory cells 12 as data.

A method for adjusting the voltage characteristics of the SRAM 10 thus configured will be described below. FIG. 5 is a flowchart illustrating an example of a voltage characteristics adjusting process for adjusting the voltage characteristics of the SRAM 10. The process is performed while the ground voltage application point Vss of each memory cell 12 is fixed at 0 V.

First, for a plurality of memory cells 12 connected to one selected word line WL of the SRAM 10, voltages are applied to supply voltage application points Vdd, the semiconductor substrate 20, the word line WL, and bit lines BLL, BLR of the memory cells 12 so that the voltage Vdd takes value V1, the substrate voltage Vsub becomes 0 V, the bit line voltage Vbll becomes 0 V, and the bit line voltage Vblr takes value V1 (step S100). This processing can force the output terminals OUTL of the plurality of memory cells 12 to be low and the output terminals OUTR to be high, thereby writing data into the plurality of memory cells 12 at once.

Then, voltages are applied to the supply voltage application points Vdd, the semiconductor substrate 20, the word line WL, and the bit lines ELL, BLR of the plurality of memory cells 12 so that the voltage Vdd takes a value V1h (for example 3.0 V) higher than value V1, the substrate voltage Vsub takes a value Vsub1 (for example −4.0 V) lower than 0 V, the word line voltage Vw1 of the word line WL selected at step S100 takes value V1, and the bit line voltages Vbll and Vblr become 0 V (step S110). The reason why the voltages are applied to the supply voltage application points Vdd, the semiconductor substrate 20, the word line WL, and the bit lines ELL, BLR will be described below.

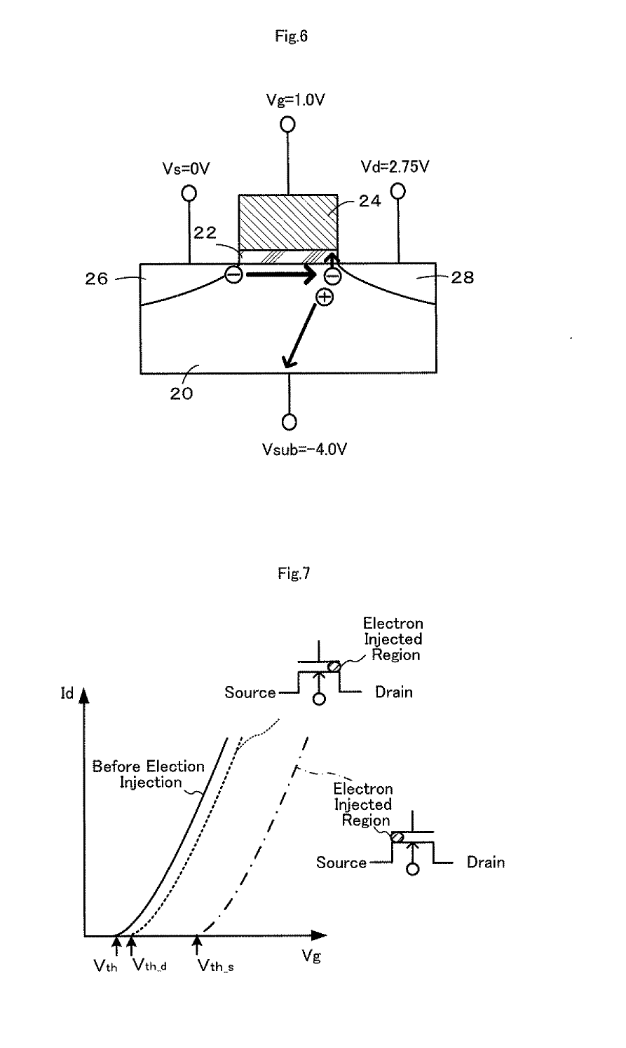

FIG. 6 is a diagram illustrating the state of a pass gate transistor PGR in the processing at step S110. As illustrated, since the drain voltage Vd, which is equal to the voltage applied to the drain minus the voltage applied to the source, is higher than a normal voltage in the pass gate transistor PGR, hot electrons are generated near the drain in the semiconductor substrate 20 due to impact ionization. Electrons generated because the gate voltage Vg, which is equal to the voltage applied to the gate minus the voltage applied to the source, is lower than the drain voltage Vd are injected into a region near the drain end of the insulating layer 22. FIG. 7 illustrates the relationship among gate voltage Vg, drain current flowing from the drain to source, and threshold voltage of a transistor in which hot electrons are injected in the insulating layer 22. In the transistor, the threshold voltage Vth s when one of the two diffusion layers 26, 28 that is adjacent to the electron-injected region in the insulating layer 22 injected with hot electrons is caused to function as the source is higher than the threshold voltage Vth_d when the one of the two diffusion layers 26, 28 that is adjacent to the electron-injected region is caused to function as the drain. Both of the threshold voltages Vth_s and Vth_d are higher than the threshold voltage Vth when hot electrons are not injected into the insulating layer 22. Accordingly, by performing the processing at step S110 force the voltage Vdd to take value V1h and force the bit line voltage Vblr to 0 V while the word line voltage Vw1 is held at V1, the voltage difference between the supply voltage application point Vdd and the bit line BLR is set to V1h higher than the normal voltage difference V1 and the voltage difference between the word line WL and the bit line BLR is set to the normal voltage difference V1 smaller than the voltage V1h, thereby injecting hot electrons into the insulating layer 22 near one of the two diffusion layers functioning as the source or drain of the pass gate transistor PGR that is connected to the output terminal OUTR of the inverter INVR. Consequently, in the pass gate transistor PGR, the threshold voltage when the diffusion layer connected to the bit line BLR is caused as the drain is higher than the threshold voltage when the diffusion layer connected to the bit line BLR is caused to function as source. Therefore, the value V1h used was determined by experiments and analysis as a voltage that enables hot electrons to be injected into the insulating layer 22 near the diffusion layer connected to the output terminal OUTR of the inverter INVR by the voltage difference between the supply voltage application point Vdd and the bit line BLR.

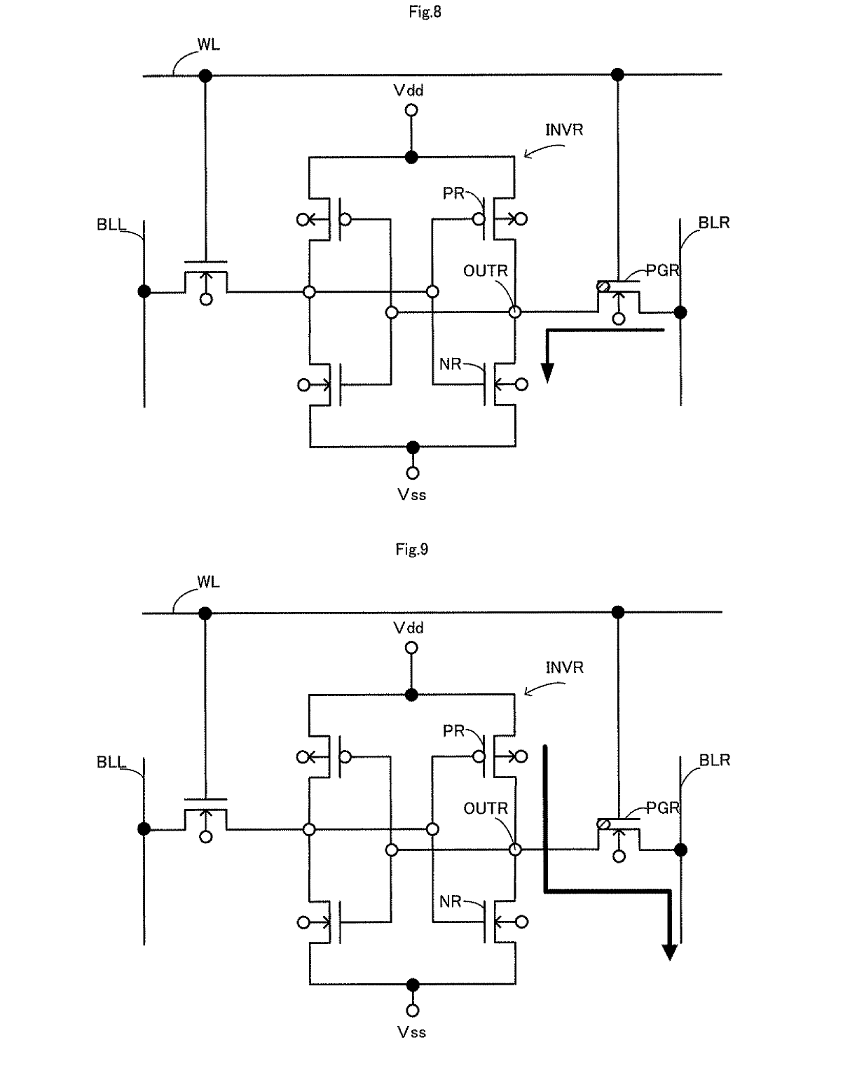

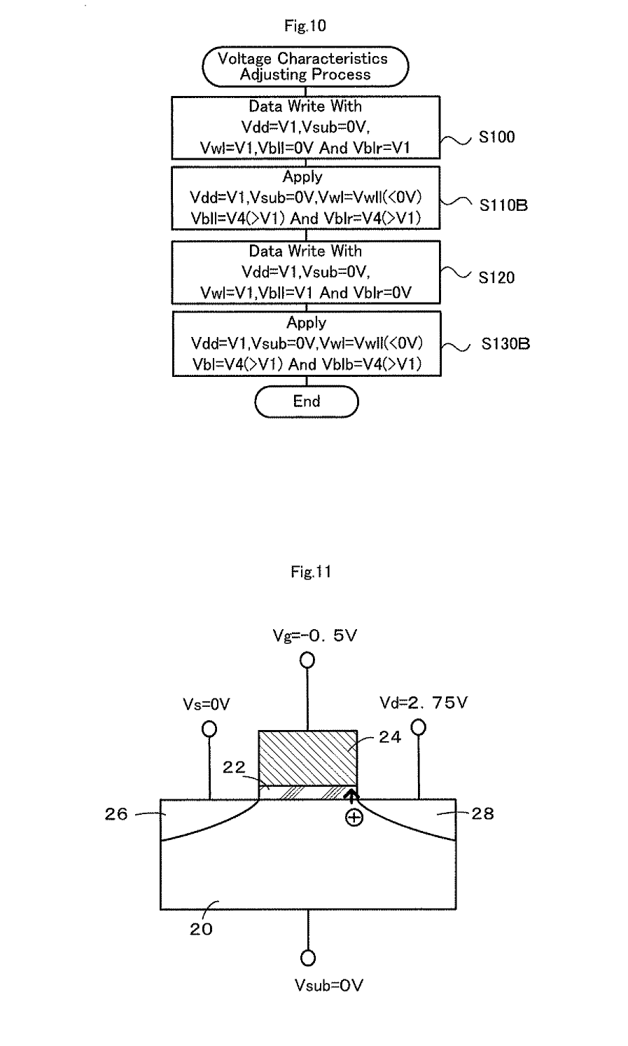

Here, consider an operation to read data from a memory cell 12. To read data, bit the lines BLL, BLR are precharge to a voltage having value V1 and are placed in a floating state, then the pass gate transistors PGL, PGR are turned on. If the output terminal OUTL of the inverter INVL holds H level data and the output terminal OUTR of the inverter INVR holds L level data, the diffusion layer connected to the bit line BLR functions as a drain and current flows from the bit line BLR to the output terminal OUTR as illustrated in FIG. 8. If the threshold voltage of the pass gate transistor PGR is low at this point in time, a large amount of current flows from the bit line BLR to the output terminal OUTR to make the voltage at the output terminal OUTR easier to invert from L level to H level. A higher threshold voltage of the pass gate transistor PGR makes the voltage at the output terminal OUTR to harder to invert and improves readout characteristics. Consider an operation to write data. If data is inverted by changing the level at output terminal OUTL from L to H and the level at output OUTR from H to L, that is, the diffusion layer connected to the bit line BLR is caused to function as a source, a current need to be flown from the output terminal OUTR to the bit line BLR to quickly lower the voltage at the output terminal OUTR to L level as illustrated in FIG. 9. Therefore a lower threshold voltage of the pass gate transistor PGR can quickly invert the voltage at the output terminal OUTR and improves write characteristics. Since the processing at step S110 makes the threshold voltage when the diffusion layer connected to the bit line BLR is caused to function as the drain higher than the threshold voltage when the diffusion layer connected to the bit line BLR is caused to function as the source as has been described above, data readout characteristics can be improved as compared with a condition where electrons are not injected into the insulating layer 22. Here, since the threshold voltage Vth_d when the diffusion layer connected to the bit line BLR is caused to function as the source is not so higher than the threshold voltage Vth before the injection of electrons, readout characteristics can be improved without significantly degrading data write characteristics. Consequently, the operating characteristics of the memory cells 12 can be improved. By setting the voltage difference between the supply voltage application point Vdd and the bit line BLR to a voltage difference V1 greater than the normal voltage difference V1 and setting the voltage difference between the word line WL and the bit line BLR to the normal voltage difference V1 smaller than the voltage V1h in this way, the operating characteristics of the memory cells 12 can be improved. In the processing at step S110, the data readout characteristics and data write characteristics of the memory cells 12 can be improved simply by adjusting the voltages to be applied to the supply voltage application points VDD, the semiconductor substrate 20, the word line WL, and the bit lines BLL, BLR. Accordingly, the operating characteristics of the memory cells 12 can be improved in a simpler way than adding the process of doping memory cells 12 with an impurity. Furthermore, since the processing at step S110 can be performed on a plurality of cells at once, the data readout characteristics of the SRAM 10 as a whole can be improved in a simpler way. Moreover, since the substrate voltage Vsub is lower than 0 V, which is the voltage applied in normal operation, the voltage at the output terminal OUTR can be increased, more hot electrons can be injected into the insulating layer 22, and the threshold voltage when the diffusion layer connected to the bit line BLR is caused to function as the drain can be increased. By performing the processing at step S100 before the processing at step S110, selection can be made between the pass gate transistors PGL and PGR to inject electrons into the insulating layer and operating characteristics can be improved more properly.

Then, voltages are applied to the supply voltage application points Vdd of the memory cells 12 selected in the processing at steps S100 and S110, the semiconductor substrate 20, the word line WL, and the bit lines BLL, BLR so that the voltage Vdd takes value V1, the substrate voltage Vsub becomes 0 V, the word line voltage Vw1 takes value V1, the bit line voltage Vbll takes value V1, and the bit line voltage Vblr becomes 0 V, thereby forcing the output terminals OUTL of the plurality of memory cells 12 high and the output terminals OUTR low to write data into the plurality of memory cells 12 at once (step S120). Then the processing at step S130, which is the same as the processing at step S110, is performed. By this process, hot electrons can be injected into the insulating layer 22 near one of the two diffusion layers functioning as the source or drain of the pass gate transistor PGL that is connected to the output terminal OUTL of the inverter INVL, and the threshold voltage when the diffusion layer of the pass gate transistor PGL that is connected to the bit line BLL is caused to function as the drain can be made higher than the threshold voltage when the diffusion layer connected to the bit line BLL is caused to function as source, thereby improving the readout characteristics of the memory cells 12. Furthermore, since the threshold voltage when the diffusion layer connected to the bit line ELL is caused to function as the drain can be made higher than the threshold voltage when the diffusion layer connected to the bit line BLL is caused to function as the source, the pass gate transistors PGL, PGR of all of the memory cells 12 connected to one word line WL turn on when the word line WL is selected in a data write operation or read operation. Accordingly, half-select disturb, which is a phenomenon in which data stored in memory cells 12 connected to bit lines BLL, BLR that are not selected by the column data 16 is inverted, can be restrained.

According to the method for adjusting the voltage characteristics of the SRAM 10 of the first embodiment described above, the operating characteristics of the memory cells 12 can be improved in a simplified way by setting the voltage difference between the supply voltage application point Vdd and the bit line BLR to V1h which is greater than the normal voltage difference V1 and setting the voltage difference between the word line WL and the bit line BLR to the normal voltage V1 which is smaller than V1h. Furthermore, since the substrate voltage Vsub is lower than 0 V which is a voltage applied in normal operation, the voltage at the output terminal OUTR can be increased, the amount of hot electrons injected into the insulating layer 22 can be increased, and the threshold voltage when the diffusion layer connected to the bit line BLR is caused to function as the drain can be increased. Moreover, by performing the processing at step S100 before the processing at step S110, selection can be made between the pass gate transistors PGL and PGR to inject electrons into the insulating layer and the operating characteristics can be improved more properly.

While the substrate voltage Vsub is forced to a value Vsub1 lower than 0 V (for example −4.0 V) in the processing at steps S100 and S110 in the method for adjusting the voltage characteristics of the SRAM 10 of the first embodiment, it is only essential to force the substrate voltage to a voltage level lower than or equal to the voltage applied to the bit lines BLL, BLR, for example to 0 V.

In the method for adjusting voltage characteristics of the SRAM 10 of the first embodiment, the processing steps S100 and S110 is performed to adjust the threshold voltage of the pass gate transistor PGR and then steps S120 and S130 are performed to adjust the threshold voltage of the pass gate transistor PGL. However, the processing at step S120 and S130 may be omitted and only the threshold voltage of the pass gate transistor PGR may be adjusted by performing only the processing at steps S100 and S110, or the processing at steps S100 and S110 may be omitted and only the threshold voltage of the pass gate transistor PGL may be adjusted by performing only the processing at steps S120 and S130. Alternatively, the processing at steps S100, S120 and S130 may be omitted and only the processing at step S110 may be performed. In these cases, although selection between the pass gate transistors PGL and PGR to inject electrons into the insulating layer cannot be made, the operating characteristics can be improved since electrons can be injected into the insulting layer of one of the pass gate transistors PGL and PGR.

A voltage characteristics adjusting method for adjusting the voltage characteristics of an SRAM 10 of a second embodiment of the present invention will be described next. The voltage characteristics adjusting process of the second embodiment is the same as the voltage characteristics adjusting process illustrated in FIG. 5, except that steps S110B and S130B are performed in place of steps S110 and S130. Therefore, the same steps are given the same reference signs and the description of those steps will be omitted.

FIG. 10 is a flowchart illustrating an example of a voltage characteristics adjusting process for adjusting voltage characteristics of the SRAM 10 of the second embodiment. In this process, first the processing at step S100 is performed to force the output terminal OUTL of each of memory cells 12 connected to a word line WL selected to L level and the output terminal OUTR to H level. Then, voltages are applied to the supply voltage application points Vdd, the semiconductor substrate 20, the word line WL, the bit lines BLL, BLR of the memory cell 12 of the SRAM 10 that are connected to the selected word line WL so that voltage Vdd takes a value V1, substrate voltage Vsub becomes 0 V, word line voltage Vw1 takes a value Vwll that is lower than an off voltage that normally turns off the word line WL (for example −0.5 V), and bit line voltages Vbll and Vblr take a value V4 (for example 2.5) (step S110B). The reason why these voltages are applied to the supply voltage application points Vdd, the semiconductor substrate 20, the word line WL, and the bit lines BLL, BLR is as follows.

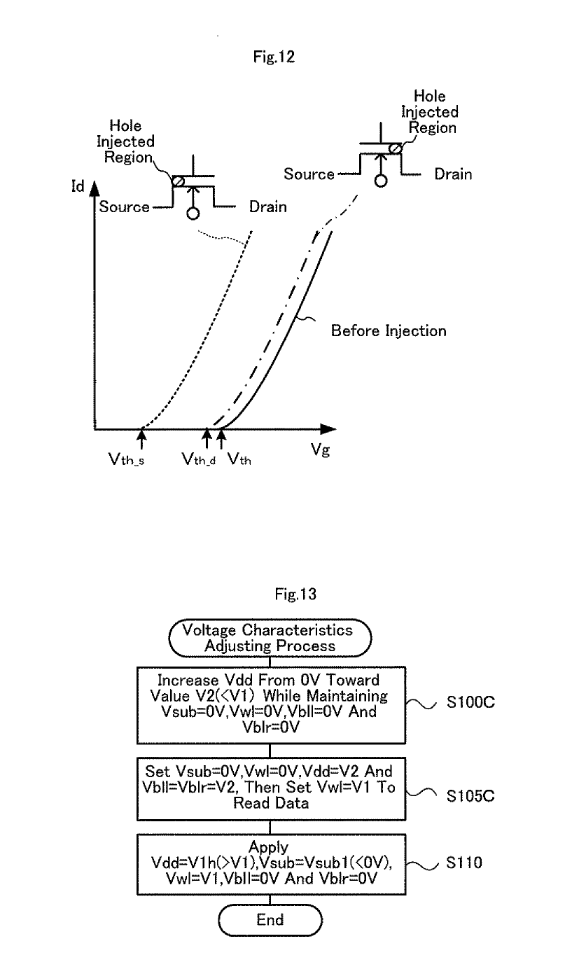

FIG. 11 is a diagram illustrating a state of a pass gate transistor PGL in the processing at step S110B. As illustrated, since the voltage difference between the drain and source of the pass gate transistor PGL is relatively large and the voltage applied to the drain is higher than the voltage applied to the gate, a high electric field is applied on the drain end under the gate while the transistor is in the off state to induce a GIDL (Gate Induced Drain Leakage) current near the drain, which injects holes into a region near the drain end of the insulating layer 22. FIG. 12 illustrates the relationship among gate voltage Vg, drain current Id and threshold voltage of the transistor in which holes are injected into the insulating layer 22. In the transistor, the threshold voltage Vth_s when one of the two diffusion layers 26, 28 that is adjacent to the hole-injected region of the insulating layer 22 into which holes are injected functions as the source is lower than the threshold voltage Vth_d when the one of the two diffusion layers 26, 28 that is adjacent to the hole-injected region functions as the drain as illustrated. Both of the threshold voltages Vth_s and Vth_d are lower than the threshold voltage Vth when holes are not injected into the insulating layer 22. By performing the processing at step S110B to force the voltage Vdd to value V1 and the bit line voltage Vbll to value V4 while maintaining the word line voltage Vw1 of the word line WL at value Vwll, the voltage difference between the supply voltage application point Vdd and the bit lines BLL, BLR is increased to a value V4 which is greater than the normal voltage difference V1 and the voltage difference between the word line WL and the he bit line BLR is increased to a value (V1+Vwll) which is greater than the normal voltage difference V1, thereby injecting holes into the insulating layer 22 near one of the two diffusion layers functioning as the source or drain of the pass gate transistor PGL that is connected to the bit line BLL. This can force the threshold voltage when the diffusing layer connected to the bit line BLL functions as the source of the pass gate transistor PGL to a voltage level lower than the threshold voltage when the diffusion layer connected to the bit line BLL functions as the drain of the pass gate transistor PGL. Since a lower threshold voltage of the pass gate transistor PGL can quickly invert the voltage at the output terminal OUTL and improve the write characteristics as has been described, the processing at step S110B can improve the write characteristics. Here, because the threshold Vth d when the diffusion layer connected to the bit line BLL is caused to function as the drain is not significantly lower than the threshold voltage Vth before injection of electrons, the write characteristics can be improved without significantly degrading data readout characteristics. Since the data write characteristics of the memory cells 12 can be improved simply by adjusting the voltages to be applied to the supply voltage application points Vdd, the semiconductor substrate 20, the word line WL, and the bit lines BLL, BLR, the data write characteristics of the memory cells 12 can be improved in a simpler way than adding the process of doping the memory cells 12 with an impurity.

Then, for the memory cells 12 that underwent the processing at steps S100 and S110B, voltages are applied to the supply voltage application points Vdd of the memory cells, the semiconductor substrate 20, the word line WL, the bit lines BLL, BLR so that the voltage Vdd takes value V1, the substrate voltage Vsub becomes 0 V, the word line voltage Vwl takes value V1, the bit line voltage Vll takes value V1, and the bit line voltage Vblr becomes 0 V to force the voltage at the output terminal OUTL of each of the memory cells 12 high and the voltage at the output terminal OUTR low (step S120), then the processing at step S130B, which is the same as the processing at step S110B, is performed. By this process, holes can be injected into the insulating layer 22 near one of the two diffusion layers functioning as the source or drain of the pass gate transistor PGR that is connected to the bit line BLR, and the threshold voltage when the diffusion layer of the pass gate transistor PGR that is connected to the bit line BLR is caused to function as the source can be made lower than the threshold voltage when the diffusion layer connected to the bit line BLR is caused to function as the drain. Consequently, the write characteristics of memory cells can be improved as compared with the equivalent in which injection of holes are not performed.

According to the method for adjusting the voltage characteristics of the SRAM 10 of the second embodiment described above, the write characteristics of the memory cells 12 can be improved in a simplified way by forcing the voltage difference between the supply voltage application point Vdd and the bit lines BLL, BLR to a value V4 greater than the normal voltage difference V1 and forcing the voltage difference between the word line WL and the bit lines BLL, BLR to a value (V1+Vwll) greater than the normal voltage difference V1. Furthermore, by performing the processing at step S100 before the processing at step 110B, selection between the pass gate transistors PGL and PGR to inject holes into the insulating layer can be made, therefore the operating characteristics can be improved more properly.

While steps S100 and S100B are performed to adjust the threshold voltage of the pass gate transistor PGR and then the steps S120 and S130B are performed to adjust the threshold voltage of the pass gate transistor PGL in the method for adjusting the voltage characteristics of the SRAM 10 of the second embodiment, steps S120, S130B may be omitted and only the threshold voltage of the pass gate transistor PGR may be adjusted by performing only steps S100 and S110B, or steps S100 and S110B may be omitted and only the threshold voltage of the pass gate transistor PGL may be adjusted by performing only steps S120 and S130B. Alternatively, steps S100, S120B and S130 may be omitted and only step S110B may be performed. In these cases, although selection between the pass gate transistors PGL and PGR to inject holes into the insulating layer cannot be made, the operating characteristics can be improved because holes can be injected into the insulting layer of one of the pass gate transistors PGL and PGR.

While the processing at steps S100 to S130B is performed to adjust the threshold voltage of the pass gate transistor PGR in the method for adjusting the voltage characteristics of the SRAM 10 of the second embodiment, processing for applying voltages to the supply voltage application points Vdd, the semiconductor substrate 20, the word line WL, and the bit lines BLL, BLR so that the voltage Vdd becomes 0 V, the substrate voltage Vsub becomes 0 V, the word line voltage Vwl takes a value Vwll (for example −0.5 V), the bit line voltage Vbll and the bit line voltage Vblr take a value V4 (for example 2.5 V) may be performed instead of the processing at steps S100 to S130B. This enables holes to be injected into both of the pass gate transistors PGL, PGR. Thus, holes can be injected in a simpler way to improve the operating characteristics of the SRAM 10.

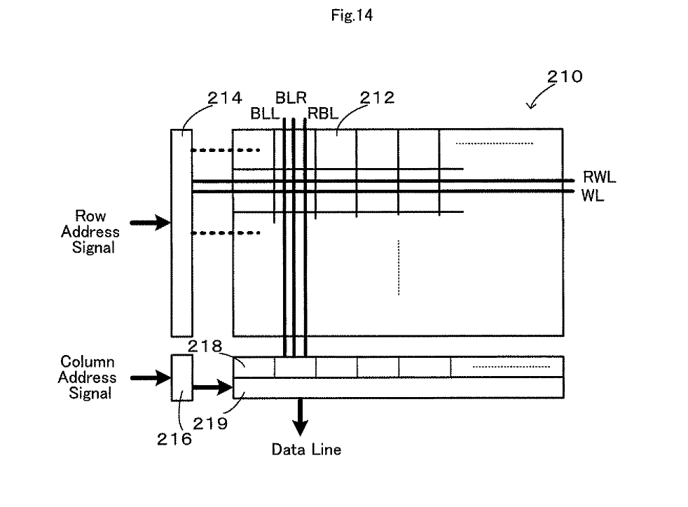

A method for adjusting the voltage characteristics of an SRAM 10 of a third embodiment of the present invention will be described next. FIG. 13 is a flowchart illustrating an example of a voltage characteristics adjusting process for adjusting the voltage characteristics of an SRAM 10 of the third embodiment. The process is performed while a ground voltage application point Vss of memory cells 12 is held at 0 V.

In this process, for a plurality of memory cells 12 connected to one word line WL selected, first voltages are applied to the semiconductor substrate 20, the word line WL, the bit lines ELL, BLR of the memory cells 12 so that all of the substrate voltage Vsub, the word line voltage Vwl, the bit line voltages Vbll, Vblr become 0 V and in this state a voltage is applied to the supply voltage application point Vdd so that the voltage Vdd changes from 0 V to a value V2 (for example 0.6 V) lower than value V1 (step S100C). Here, the value V2 is determined beforehand by experiments and analysis as a voltage that holds the voltage of the output terminals OUTL, OUTR high or low due to a difference between threshold voltages of the transistors PL, PR, NL and NR that appear as the voltage Vdd was gradually increased from 0 V. This process causes transistors that have a lower threshold voltage turn on first among the transistors PL, PR, NL and NR, and the voltages at the output terminals OUTL, OUTR are determined by which of the transistors turn on. For example, if the threshold voltage of the transistors PR, NL is lower than the threshold voltage of the transistors PL, NR, the transistors PR, NL turn on first and the output terminal OUTL of the memory cell 12 is forced high and the output terminal OUTR is forced low. For illustrative purposes, it is assumed hereinafter that once the processing at step S100B has been performed, the output terminal OUTL of the memory cell 12 is held high and the output terminal OUTR is held low. By the processing at step S100B, data reflecting the difference between threshold voltages of the transistors PL, PR, NL, NR is held in the memory cell 12.

Then, the word line voltage Vwl and the substrate voltage Vsub are set to 0 V and the voltage Vdd at the supply voltage application point Vdd is set to value V2, and the bit lines BLL, BLR are precharged to a bit line voltage Vbll, Vblr of V2. Then, the bit lines BLL, BLR are placed in an electrically floating state. Then a voltage is applied to the word line WL so that the word line voltage Vwl takes value V1, and performs a data read operation (step S105C). As in the processing at step S110 of the voltage characteristics adjusting process illustrated in FIG. 5, for a plurality of memory cells 12 connected to one word lines WL, voltages are applied to supply voltage application point Vdd of each memory cell 12, the semiconductor substrate 20, the word line WL, the bit lines ELL, BLR so that the voltage Vdd takes value Vlh, the substrate voltage Vsub takes value Vsubl that is lower than 0 V, the word line voltage Vwl takes value V1, and the bit line voltage Vbll and the bit line voltage Vblr become 0 V (step S110). The reason why the processing at step SIO5C is performed is as follows. For example, if the threshold voltage of the pass gate transistor PGR, the threshold voltage of the transistor PL and the threshold voltage of the transistor NR are lower, the output terminal OUTL is likely to go low and the output terminal OUTR is likely to go high when data is read out. Therefore, a read operation at step S105C is performed to ensure that the voltage of one of the output terminals OUTL and OUTR that is connected to the pass gate transistor PGR having a lower threshold voltage is forced high. Step S110 is performed in this state to inject electrons into the pass gate transistor PGL, PGR connected to one of the output terminals OUTL, OUTR that is high. Accordingly, the threshold voltage of the pass gate transistor injected with electrons can be increased when data is read. This can improve the readout characteristics of the memory cells 12.

According to the method for adjusting the voltage characteristics of the SRAM 10 of the third embodiment described above, while voltages are being applied to the semiconductor substrate 20 of the memory cells 12, the word line WL and the bit lines BLL, BLR so that all of the substrate voltage Vsub, the word line voltage Vwl, and the bit line voltages Vbll, Vblr become 0 V, a voltage is applied to the supply voltage application point Vdd to change the voltage Vdd from 0 V to a value V2 that is lower than value V1. Then a voltage is applied to the word line WL so that the word line voltage Vw1 takes value V1, and a data read is performed. Then, voltages are applied to the supply voltage application points Vdd of the memory cells of the SRAM 10, the semiconductor substrate 20, the word line WL, and the bit lines BLL, RLR so that the voltage Vdd takes value V1h, the substrate voltage Vsub takes value Vsubl that is lower than 0 V, the word line voltage Vwll takes value V1, and the bit line voltage Vbll and the bit line voltage Vblr become 0 V. Consequently, the readout characteristics of the memory cells 12 can be improved.

While the processing at step S1OSC and the processing at step S110 are performed once in the method for adjusting voltage characteristics of the SRAM 10 of the third embodiment, the processing at step S105C and the processing at step S110 may be performed more than once. Each time the processing at step S105C is performed, the output terminal voltage output to one of the pass gate transistors PGL, PGR whose threshold voltage should be higher when a data read operation is performed goes high and, in the subsequent processing at step S110, electrons are injected into the pass gate transistor whose threshold voltage should be higher when a read operation is performed. This prevents the threshold voltage of only one of the pass gate transistors from excessively increasing.

While the same processing as the processing at step S110 of the voltage characteristics adjusting process illustrated in FIG. 2 is performed after the processing at step S105C in the process for adjusting the voltage characteristics of the SRAM 10 of the third embodiment, the same processing as step S110B of the voltage characteristics adjusting method illustrated in FIG. 10 may be performed instead of the processing at step S110. This can improve the write characteristics of the SRAM 10.

While the voltage adjusting process described above is performed on the memory cells 12 connected to a selected word line WL of the SRAM 10 at once in the voltage characteristics adjusting process of the first to third embodiments, the voltage characteristics adjusting process may be performed on all of the memory cells 12 of the SRAM 10 at once, or on each of blocks into which the SRAM 10 is divided or only on some of the memory cells 12 of the SRAM 10 at a time.

While the voltage characteristics adjusting process of the present invention is applied to a circuit including transistors PL, PR, NL, and NR having the structures illustrated in FIGS. 3 and 4 in the first to third embodiment, the voltage characteristics adjusting process may be applied to circuit in which transistors Pl, PR are formed on a n-conductivity-type semiconductor substrate and transistors NL, NR are formed in a p-conductivity type well formed in the n-conductivity-type semiconductor substrate.

While each of the memory cells 12 of the SRAM 10 includes an inverter INVL made up of transistors PL, NL and an inverter INVR made up of transistors PR, NR in the first to third embodiments, the inverters INVL, INVR may have any configuration that inverts the logic of a voltage input through the input terminal and outputs the inverted voltage through the output terminal. For example, resistance elements having a relatively high resistivity may be used instead of the transistors PL, PR.

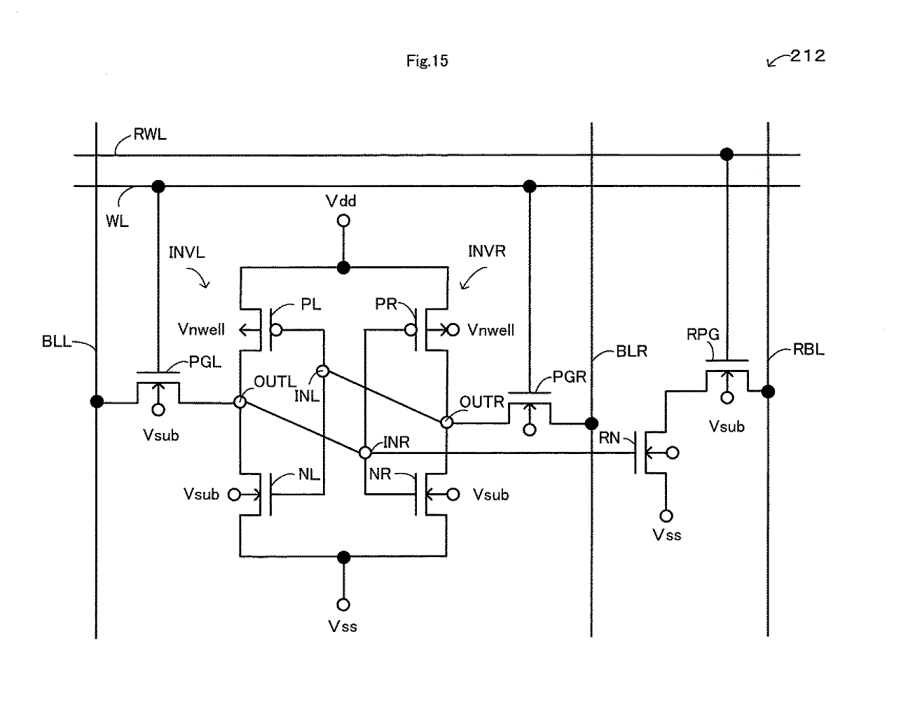

While the voltage characteristics adjusting method of the present invention is applied to the SRAM 10 in the first to third embodiments, the voltage characteristics adjusting method may be applied to an SRAM 210 including, as illustrated in FIG. 14, a plurality of memory cells 212 connected to a plurality of read-only word lines RWL and read-only bit lines RBL in addition to a plurality of word lines WL and bit lines BLL, BLR, a row decoder 214 selecting a word line WL or a read-only bit line RBL when a row address signal is provided, a column decoder 216 selecting a pair of bit lines BLL, BLR or one read-only bit line RBL that corresponds to a column address signal when the column address signal is provided, a plurality of sense amplifiers 218 amplifying signals output from the memory cells 212 to the read-only bit line RBL, a column select circuit 219 connecting selected bit lines BLL, BLR, and read-only bit line RBL with a data line, not depicted, through which data is input and output. A configuration of each memory cell 212 and an operation of the SRAM 210 will be described below. FIG. 15 is a circuit diagram schematically illustrating a memory cell 212 of the variation. The memory cell 212 includes, in addition to the components of the memory cell 12, an re-channel MOS transistor RN (hereinafter referred to as transistor RN) having a gate connected to an input terminal INR and a source connected to a ground voltage application point Vss and an n-channel MOS transistor RPG (hereinafter referred to as read-only pass gate transistor RPG) having a gate connected to a read-only word line RWL, a source connected to a read-only bit line RBL, and a drain connected to the drain of the transistor RN. In the SRAM 210 thus configured, a data write operation is performed in the same way as in the SRAM 10 described above while all of the read-only word lines RWL are placed in the deselected state (at a voltage of 0 V) and the read-only pass gate transistor RPG is in the off state. A data read operation is performed by reading a voltage on the read-only bit line RBL that appears according to a voltage at the output terminal OUTL in the memory cell 212 connected to a read-only word line RWL selected by the row decoder 14 and to a read-only bit line RBL selected by the column decoder 16 while all of the word lines WL are placed in the deselected state. A data hold operation is performed by placing all of the word lines WL, read-only word lines RWL, bit lines BLL, BLR, and read-only bit lines RBL in the deselected state and turning off the pass gate transistors PGL, PGR, and the read-only pass gate transistor RPG to hold the voltage at the output terminals OUTL, OUTR of the memory cell 12 as data. In the SRAM 210, the operating characteristics of the memory cells 212 can be improved by performing any of the voltage characteristics adjusting processes illustrated in FIGS. 5, 10 and 13 while all of the read-out bit lines RBL are placed in the deselected state.

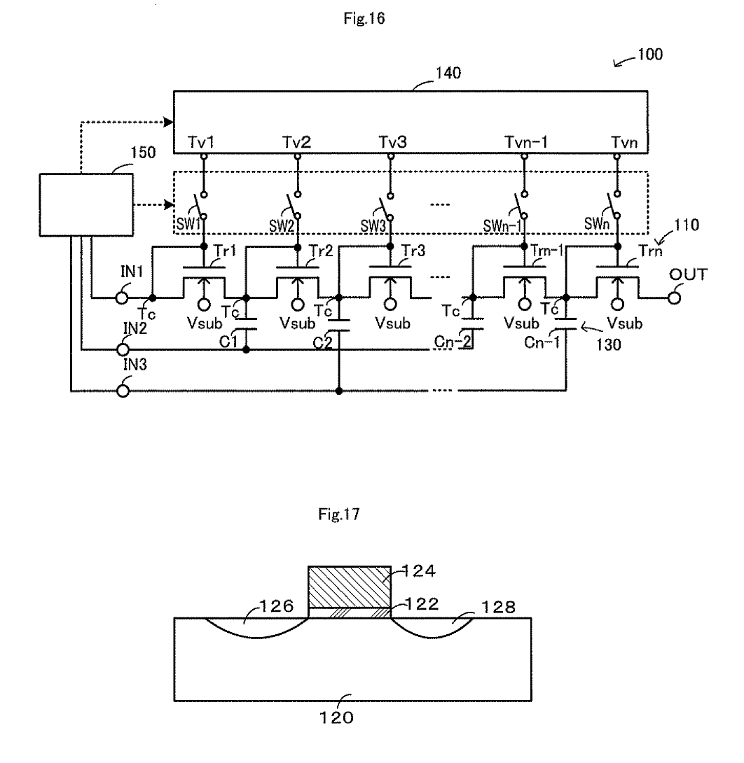

FIG. 16 is a diagram schematically illustrating a configuration of a charge pump 100 of an embodiment of the present invention. The charge pump 100 includes three input terminals IN1 to IN3, an output terminal OUT, a multi-stage transistor circuit 110 made up of n transistors Tr1 to Trn connected in series, a capacitor circuit 130 including (n−1) capacitors C1 to Cn−1 connected to the transistors Tr2 to Trn of the multi-stage transistor circuit 110, excluding the transistor Tr1 at the first stage, n switches SWI to SWn connected to the transistors Tr1 to Trn of the multi-stage transistor circuit 110, a control voltage supply circuit 140 supplying a voltage to each of n control terminals Tv1 to Tvn connected to the switches SW1 to SWn, and a control circuit 150 which supplies a voltage or a clock signal to the three input terminals IN1 to IN3 individually, controls the switches SW1 to SWn to turn on and off, and controls a voltage supplied from the control voltage supply circuit 140 to the control terminals Tv1 to Tvn.

Each of the transistors Tr1 to Trn of the multi-stage transistor circuit 110 includes a connection terminal Tc to which one of its source and drain and its gate are connected and the other of the source and drain is connected to the connection terminal Tc of an adjacent transistor, thereby the transistors Tr1 to Trn are interconnected in series. The connection terminal Tc of the transistor Tr1 at the first stage is connected to the input terminal IN1 and the source of the transistor Trn at the last stage is connected to the output terminal OUT. As illustrated in FIG. 17, each of the transistors TR1 to Trn is configured as a well-known n-channel MOS transistor, which includes an insulating layer 122 formed of a material having a high insulation performance, such as a silicon dioxide (SiO₂), on a semiconductor substrate 120 made of a semiconductor, material such as silicon (Si), controlled to p-conductivity type, a gate electrode 124 formed of a metallic material such as polysilicon on the insulating layer 122, and two diffusion layers 126, 128 of n-conductivity type which are formed in the semiconductor substrate 120 both sides of an lower region of the insulating layer 122 of the semiconductor substrate 120 and function as a source or drain.

Each of the capacitors C1 to Cn−1 of the capacitor circuit 130 is connected between the connection terminal Tc of each of the transistors Tr2 to Trn, excluding the transistor Tr1 at the first stage, and the input terminal Int or the input t inal In3. The capacitors C1 to Cn−1 are alternately connected to the input terminal IN2 or IN3 in such a manner that a capacitor adjacent to a capacitor connected to the input terminal IN2 is connected to the input terminal IN3.

Each of the switches SW1 to SWn is connected between the control terminal Tv1 to Tvn and the connection terminal Tc and gate of each of the transistors Tr1 to Trn of the multi-stage transistor circuit 110 so as to turn on and off the supply of a voltage from the control terminal Tv1 to Tvn to the connection terminal Tc and gate of each of the transistors Tr1 to Trn.

When the charge pump 100 thus configured is in a normal operation, all of the switches SW1 to SWn are turned off and a supply voltage Vdd (for example 3 V) is supplied from the control circuit 150 to the input terminal In1 and, in this state, a clock signal CLK is input into the input terminal IN2 and an inverted clock signal CLKB having a logic that is the inverse of the logic of the clock signal CLK is input into the input terminal IN3, in response to these signals CLK and CLKB, the supply voltage Vdd from the input terminal IN is increased to a predetermined level (for example 20 V) and is output from the output terminal OUT.

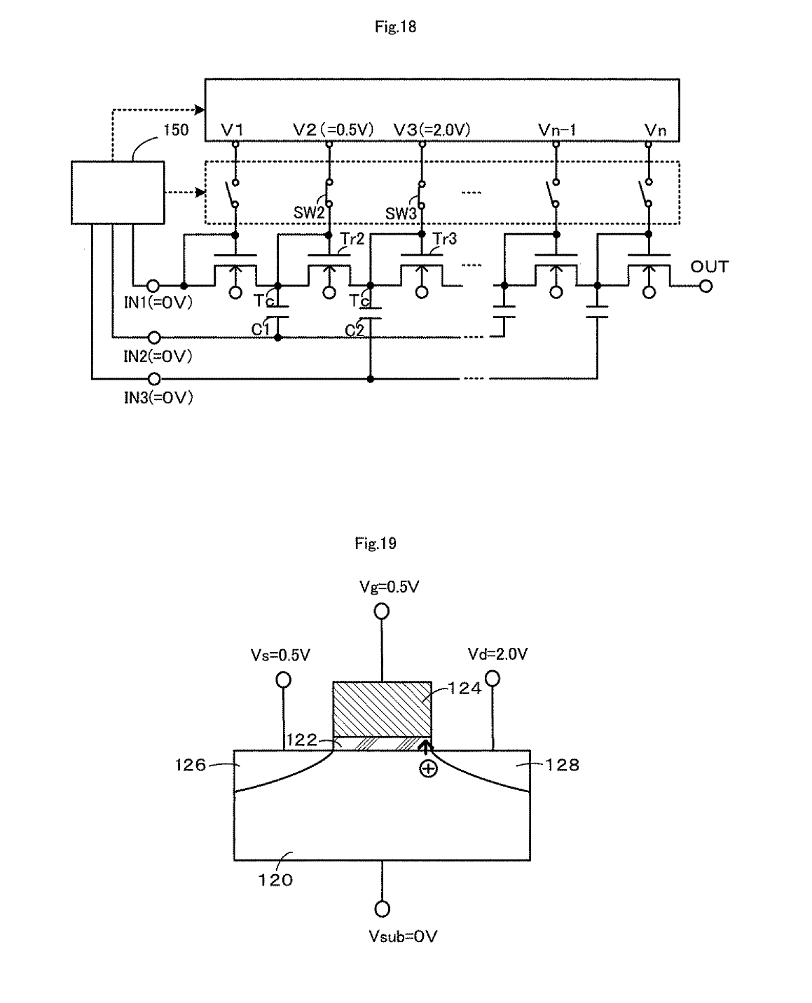

A method for adjusting the voltage characteristics of the charge pump 100 thus configured will be described next. FIG. 18 is a diagram illustrating the charge pump 100 during adjustment of the voltage characteristics. To adjust the voltage characteristics of the charge pump 100, the control circuit 150 controls the switches SW1 to Swn to sequentially turns on the switches SW1 to SWn in such a manner that two adjacent switches among the n switches Sw1 to SWn turn on at a time (for example, switches SW1 and SW2, switches SW2 and SW3, switches SW3 and SW4, and so on) while holding the input terminals In1, In2 at 0 V, and controls the control voltage supply circuit 140 so that a voltage having a value V5 is applied to one of the control terminals connected to the two switches in the on state that is nearer to the transistor Tr1 at the first stage of the multi-stage transistor circuit 110 (for example the control terminal Tv2 when the switches SW2 and SW3 are in the on state) and a predetermined high voltage VH (for example 2.0 V) higher than the supply voltage Vdd is applied to the control terminal nearer to the transistor Trn of the multi-stage transistor circuit 110 (for example the control terminal Tv3 when the switches SW2 and SW3 are in the on stage). The reason why these voltages are applied will be described below.

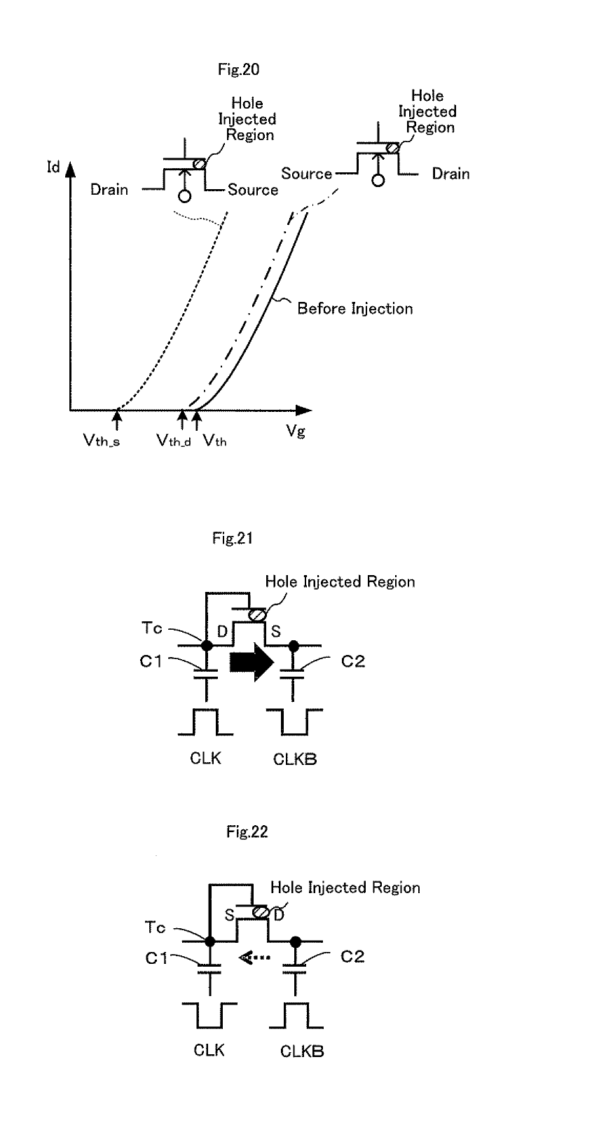

FIG. 19 is a diagram illustrating a state of the transistor Tr2 in FIG. 18. Since the voltage applied to the drain of the transistor Tr2 is higher than the voltage applied to the gate as illustrated, a high electric field is applied on the drain end under the gate of the transistor in the off state to induces GIDL (Gate Induced Drain Leakage) current near the drain, which injects holes into a region in the insulating layer 122 near the drain end. FIG. 20 illustrates the relationship among gate voltage Vg, drain current Id flowing from the drain to the source, and threshold voltage of the transistor in which holes are injected in the insulating layer 122 as described above. As illustrated, in the transistor, threshold voltage Vth_s when one of the two diffusion layers 126, 128 that is adjacent to the hole-injected region in the hole-injected insulating layer 122 is caused to function as source is lower than the threshold voltage Vth_d when the one of the diffusion layers 126, 128 that is adjacent to the hole-injected region is caused to function as the drain, and both of the threshold voltages Vth_s and Vth_s are lower than the threshold voltage when holes are not injected into the insulating layer 122. That is, since holes are injected into the insulating layer 122 near one of the two diffusion layers that functions as the source or drain of the transistor Tr2 that is connected to the connection terminal Tc of the transistor Tr3, the threshold voltage when the diffusion layer in the transistor Tr2 that is connected to the connection terminal Tc of the transistor Tr3 is caused to function as the source of the transistor Tr2 is lower than the threshold voltage when the diffusion layer connected to the connection terminal of the transistor Tr3 is caused to function as the drain. FIGS. 21 and 22 are diagrams illustrating a voltage increasing operation performed in the hole-injected transistor Tr2 as described above. When the clock signal CLK rises, a current flows from the transistor Tr2 toward the transistor Tr3 to charge the capacitor C2. At this point in time, the diffusion layer in the transistor Tr2 that is connected to the connection terminal Tc of the transistor Tr3 functions as the source and therefore the threshold voltage of the transistor Tr2 is lower than when the holes are not injected into the transistor Tr2, and the current flowing through the transistor Tr2 increases, which facilitates charging the capacitor C2 to more significantly increase the voltage at the connection terminal Tc of the transistor Tr3. That is, the voltage at the connection terminal Tc of the transistor Tr3 can be more significantly increased at one rise of the clock signal CLK. When the clock signal CLK falls, the voltage at the connection terminal Tc of the transistor Tr2 decreases and the diffusion layer connected to the connection terminal Tc of the transistor Tr2 functions as the source, as illustrated in FIG. 22, therefore the threshold voltage of the transistor Tr2 becomes higher than when the clock signal CLK is high, the current flowing through the transistor Tr2 decreases, which restrains discharging of the capacitor C2 to restrain drop of the voltage at the connection terminal Tc of the transistor Tr3. That is, drop of the raised voltage at the connection terminal Tc of the transistor Tr3 due to one fall of the clock signal is restrained. This means that the efficiency of voltage rising by the charge pump 100, and hence the operating characteristics, can be increased. In this way, the operating characteristics of the charge pump 100 can be improved by adjusting the voltage characteristics of the charge pump 100 by controlling the n switches SW1 to SWn to turn on the switches SW1 to SWn in sequence in such a manner that two adjacent switches among the n switches SW1 to SWn turn on at a time while holding the input terminal IN1 and IN2 at 0 V and controlling the control voltage supply circuit 140 to apply a voltage having value V5 to one of the connection terminals connected to the two switches in the on state that is nearer to the transistor Tr1 at the. first stage of the multi-stage transistor circuit 110 and apply a predetermined high voltage VH higher than the supply voltage Vdd to the other control terminal nearer to the transistor Trn at the last stage of the multi-stage transistor circuit 110.

In the charge pump 100 of this embodiment of the present invention, the n switches SW1 to SWn are controlled so that two adjacent switches among the n switches SW1 to SWn are turned on while the input terminals IN1 and 1N2 are held at 0 V and the control voltage supply circuit 140 is controlled to apply a voltage having value V5 to one of the control terminals connected to the two switches in the on state that is nearer to the transistor Tr1 at the first stage of the multi-stage transistor circuit 110 and apply a predetermined high voltage VH higher than the supply voltage Vdd to the control terminal nearer to the transistor Trn at the last stage of the multi-stage transistor circuit 110. This can improve the voltage characteristics and operating characteristics of the charge pump 100.

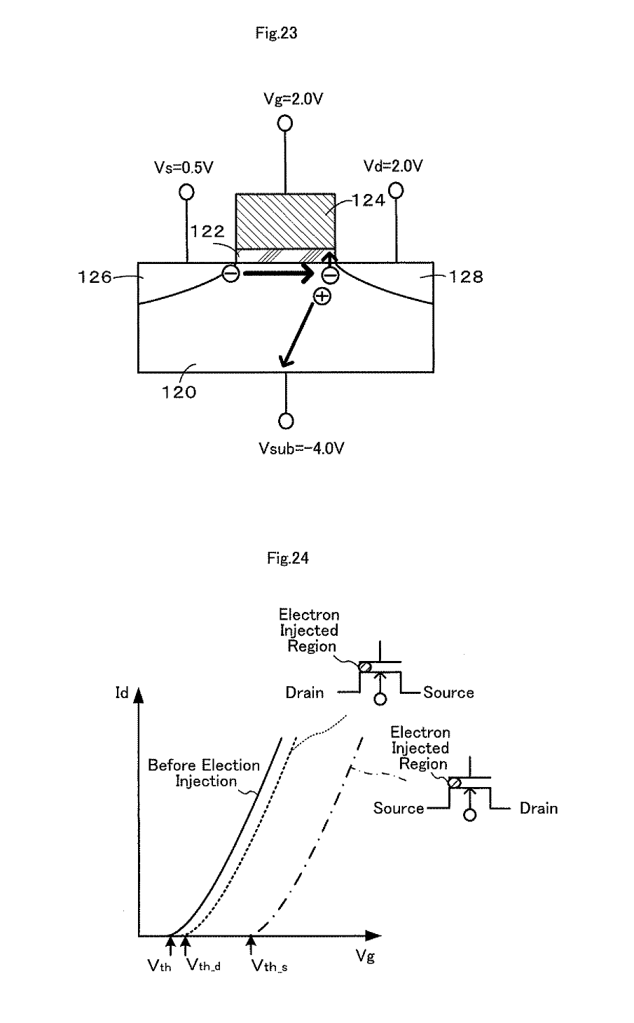

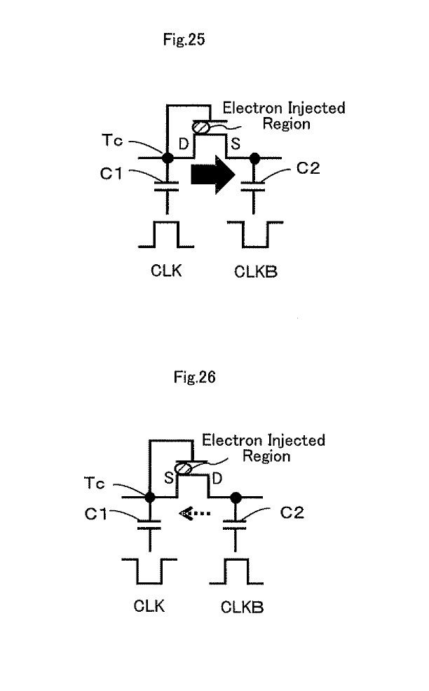

While the n switches SW1 to SWn are controlled so that two adjacent switches among the n switches SWI to SWn are turned on while the input terminals IN1 and 1N2 are held at 0 V and the control voltage supply circuit 140 is controlled to apply a voltage having value V5 to one of the control terminals connected to the two switches in the on state that is nearer to the transistor Tr1 at the first stage of the multi-stage transistor circuit 110 and apply a predetermined high voltage VH higher than the supply voltage Vdd to the control terminal nearer to the transistor Trn at the last stage of the multi-stage transistor circuit 110 in the charge pump of this embodiment, the control voltage supply circuit 140 may be controlled to apply a predetermined high voltage VH higher than the supply voltage Vdd to one of the control terminals connected to the two switches in the on state that is nearer to the transistor Tr1 at the first stage of the multi-stage transistor circuit 110 and apply a voltage having value V5 to the control terminal nearer to the transistor Trn at the last stage of the multi-stage transistor circuit 110. FIG. 23 is a diagram illustrating a state of the transistor Tr2 when a predetermined high voltage VH is supplied to the control terminal Tv2 and a voltage having value V5 is supplied to the control terminal Tv3 in FIG. 18. As illustrated, since the drain voltage Vd, which is equal to the voltage applied to the drain minus the voltage applied to the source, is high in the transistor Tr2, impact ionization generates hot electrons near the drain in the semiconductor substrate 20 and electrons generated because the gate voltage Vg, which is equal to the voltage applied to the gate minus the voltage applied to the source, is lower than the drain voltage Vd are injected into a region near the drain end of the insulating layer 122. FIG. 24 illustrates the relationship among gate voltage Vg of the transistor in which hot electrons are injected into the insulating layer 122, drain current Id flowing from the drain to source, and threshold voltage. In the transistor, as illustrated, the threshold voltage Vths when one of the two diffusion layers 26 and 27 that is adjacent to the electron-injected region in the insulating layer 122 injected with hot electrons is caused to function as the source is higher than the threshold voltage Vthd when the one of the diffusion layers 26 and 28 that is adjacent to the hole-injected region is caused to function as the drain, and both of the threshold voltages Vth_s and Vth_d are higher than the threshold voltages when hot electrons are not injected into the insulating layer 122. FIGS. 25 and 26 are diagrams illustrating a voltage increasing operation performed in the electron-injected transistor Tr2. When the clock signal CLK rises, one of the diffusion layers of the transistor Tr2 that is connected to the connection terminal Tc of the transistor

Tri functions as the source as illustrated in FIG. 25 and therefore the threshold voltage of the transistor Tr2 is approximately equal to the threshold voltage when electrons are not injected into the transistor T2. When the clock signal CLK falls, the voltage at the connection terminal Tc of the transistor Tr2 decreases and the diffusion layer connected to the connection terminal Tc of the transistor Tr2 functions as the source as illustrated in FIG. 26, therefore the threshold voltage of the transistor Tr2 becomes higher than the threshold voltage when the clock signal CLK is high. This means that the efficiency of the voltage rising by the charge pump 100, and hence the operating characteristics of the charge pump 100, can be increased.

While the transistors Tr1 to Trn of the multi-stage transistor circuit 110 are connected with the control terminals Tv1 to Tvn through switches SW1 to Swn in the charge pump 100 of this embodiment, any means capable of turning on and off may be used to connect the transistors Tr1 to Trn of the multi-stage transistor circuit 110 with the control terminals Tv1 to Tvn. For example, transistors that turn on and off depending on a voltage input into the gates may be used.

While the charge pump 100 of this embodiment is made up of transistors formed on the p-conductive-type semiconductor substrate 120 as illustrated in FIG. 19, the charge pump 100 may be made up of transistors formed on an n-conductivity-type semiconductor substrate.

While a mode that is a charge pump has been described in this embodiment, another mode may be a method for adjusting the voltage characteristics of such a charge pump.

A method for adjusting the voltage characteristics of an SRAM 410 of a fourth embodiment of the present invention will be described next. Here, the SRAM 410 whose voltage characteristics are to be adjusted has the same configuration as the SRAM 10 of the first embodiment, except that column switches 420 are provided between bit lines BLL, BLR and a sense amplifier 18, that a voltage different from a voltage supplied to a supply voltage application point Vdd of each memory cell 12 can be applied to a supply voltage of peripheral circuitry (a row decoder 14, a column decoder 16, the sense amplifier 18, and a column select circuit 19), and that precharge circuits 422 that precharge bit lines BLL, BLR to the supply voltage of the peripheral circuit. Therefore, the same components as those of the SRAM 10 of the first embodiment are given the same reference signs as those used for the SRAM 10 and description of those components will be omitted.

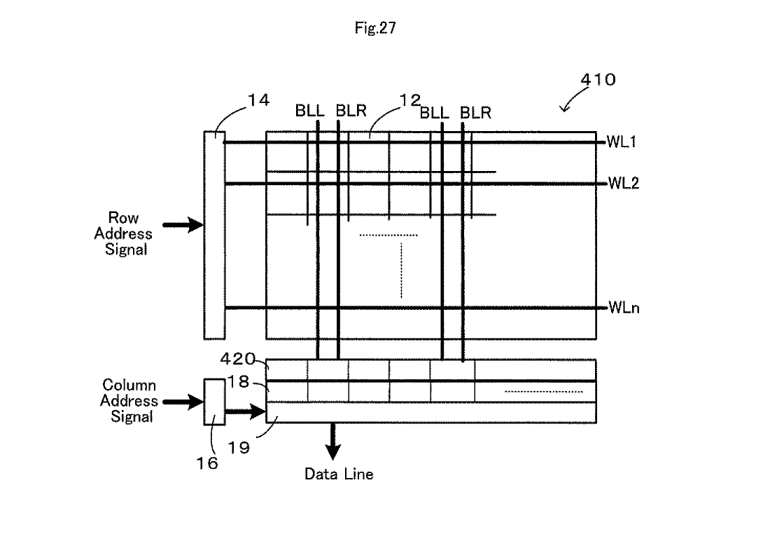

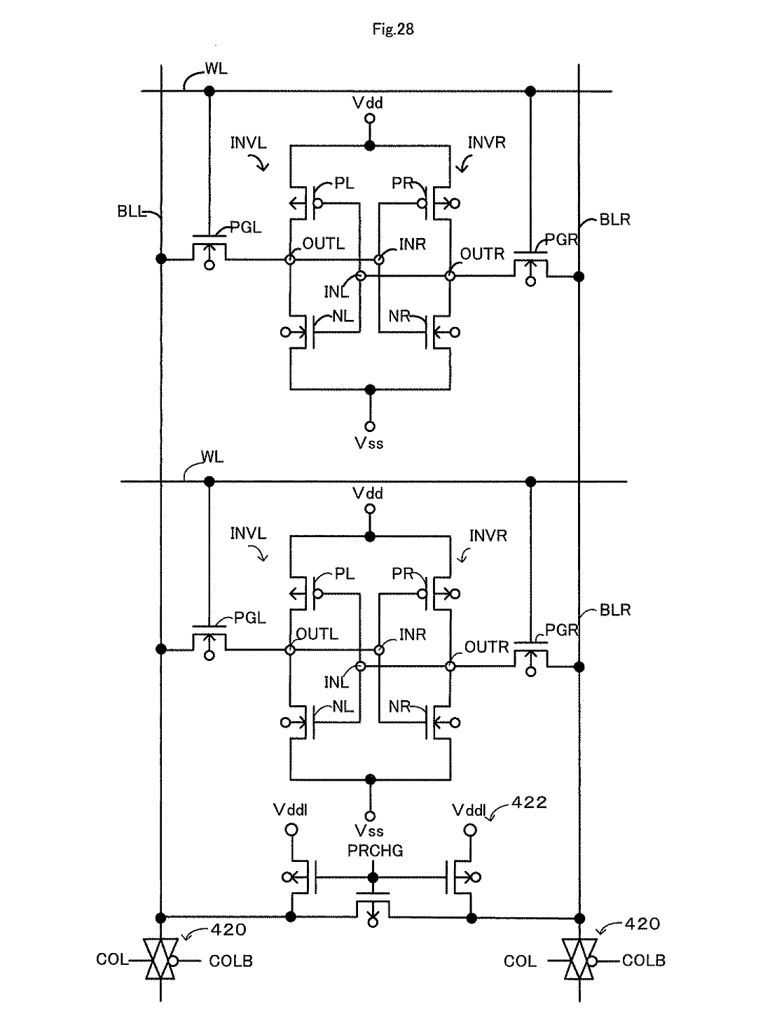

FIG. 27 is a diagram schematically illustrating a configuration of the SRAM 410 which includes a plurality of memory cells 12 and whose voltage characteristics are to be adjusted by the voltage characteristics adjusting method of the fourth embodiment of the present invention. FIG. 28 is a diagram schematically illustrating a configuration of a subject part of the SRAM 410. The SRAM 410 includes n×m memory cells 12 which are connected to n word lines WL1 to WLn and m bit lines BLL, BLR and are arranged in a matrix of n rows and m columns, and column switches 420 which are provided between the bit lines BLL, BLR and the sense amplifier 18 and electrically connect and disconnect the bit lines BLL, BLR to and from the sense amplifier 18. The SRAM 410 is configured to be able to apply a voltage Vdd1 (for example 1.0 V) that is different from a voltage supplied to the supply voltage application point Vdd of each of the memory cells 12.

Each of the column switch 420 is configured as a well-known CMOS switch which turns on and off in response to column signals COL, COLE (the column signal COL and the column signal COLE have opposite phases). When the column signal COL is high, the column switch 420 turns on to electrically connect bit lines ELL, BLR to the sense amplifier 18; when the column signal COL is low, the column switch 420 turns off to electrically disconnect the bit lines BLL, BLR from the sense amplifier 18.

Precharge circuits 422 are provided which precharge the bit lines BLL, BLR to a voltage Vdd1 of the peripheral circuitry of the bit lines BLL, BLR of the SRAM 410. Each of the precharge circuits 422 includes two p-channel MOS transistors, each having a gate into which a precharge signal PRCHG is input and a drain to which the supply voltage Vdd1 of the peripheral circuitry is applied and which is connected to bit line BL or BLB and a p-channel MOS transistor having a gate into which a precharge signal PRCHG is input and a drain and a source which are connected to the bit line BL or BLB. When the precharge signal PRCHG is low (0 V), the precharge circuit 422 turns on three p-channel MOS transistors to precharge the bit lines BL, BLB to the supply voltage Vdd1 of the peripheral circuitry; when the precharge signal PRCHG is high (value V1), the precharge circuit 422 turns off the three p-channel MOS transistors.

Specifically, an operation to write data into the SRAM 410 thus configured is performed as follows. When signals such as a row address signal and a column address signal that are required for the operation are provided and the voltages of the bit lines BLL, BLR (hereinafter referred to as bit line voltages Vbll, Vblr) are forced to voltage levels corresponding to data to be written, one WL of n word lines WL1 to WLn is selected by the row decoder 14 on the basis of the row address signal and the voltage of the selected word line WL (hereinafter referred to as word line voltage Vw1) is forced to a value V1. On the other hand, a pair of bit lines BLL, BLR is selected by the column decoder 16 on the basis of the column address signal and a column signal COL is input to turn on the column switches 420 of the selected bit lines. This operation forces the output terminals OUTL, OUTR of the memory cell 12 connected to the selected word line WL and bit lines BLL, BLR to voltages corresponding to the voltages of the bit lines BLL, BLR, thereby enabling data to be written into the memory cell 12.

An operation to read data from the SRAM 410 is performed as follows. When signals such as a row address signal and column address signal that are required for the operation are provided, a precharge signal PRCHG (0 V) is input into the precharge circuit 422 connected to the bit lines BLL, BLR selected by the column decoder 16 to turn on the precharge circuit 422 and a column signal is input to turn on the column switches 420 connected to the selected bit lines BLL, BLR, thereby precharging the bit lines BLL, BLR to voltage Vdd1 first. Then, a precharge signal PRCHG (value V1) is input into the precharge circuit 422 to turn off the precharge circuit 422 and voltage Vdd is applied to the word line selected from among the n word lines WL1 to WLn by the decoder 14 to read the voltage difference between the bit lines BLL and BLR caused in accordance with the voltage difference between the output terminals OUTL and OUTR of each of the memory cells 12 connected to the selected word line WL1 and bit lines BLL, BL through the sense amplifier 18 as data.

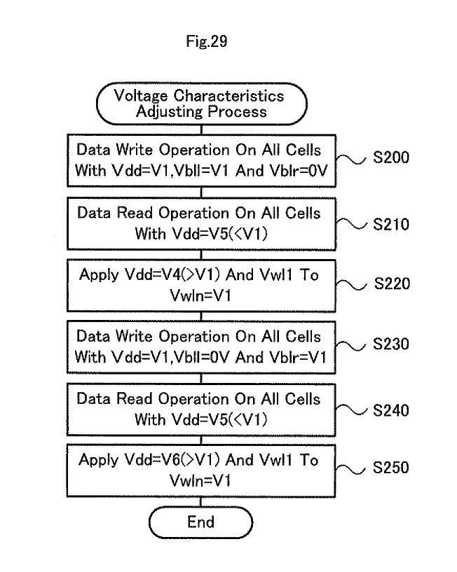

A method for adjusting the voltage characteristics of the SRAM 410 thus configured will be described next. FIG. 29 is a flowchart illustrating an example of a voltage characteristics adjusting process for adjusting the voltage characteristics of the SRAM 210. The process is performed while the ground voltage application point Vss of each memory cell 12 is held at 0 V and the substrate voltage Vsub is held at 0 V.

First, a voltage having value V1 is applied to the voltage Vdd, a voltage having value V1 is applied to each of the bit lines BLL, and a voltage of 0 V is applied to each of the bit lines BLB to perform a data write operation on all of the memory cells 12 of the SRAM 410 (step S200). This operation can force the output terminals OUTL of all of the memory cells 12 high and the output terminals OUTR low.

Then, a voltage having a small value V5 (for example 0.5 V) is applied to the voltage Vdd to perform a data read operation on all of the memory cells 12 (step S210). If the threshold voltage of the pass gate transistor PGR of a memory cell 12 is lower than the other transistors (transistors PL, NL, PR, LR and pass gate transistor PGL) of the same memory cell 12 and the current balance among the transistors is not proper, the voltage at the output terminal OUTR will be higher than the voltage at the output terminal OUTL and the data will be inverted. Such inversion of data occurs only in memory cells among the cells 12 where current balance among the transistors is improper. The processing at step S210 can invert data in such memory cells where current balance among the transistors is improper. Therefore, a voltage that inverts the voltages at the output terminals OUTL, OUTR of memory cells where current balance among transistors is improper was determined by experiments and analysis and used as value V5.

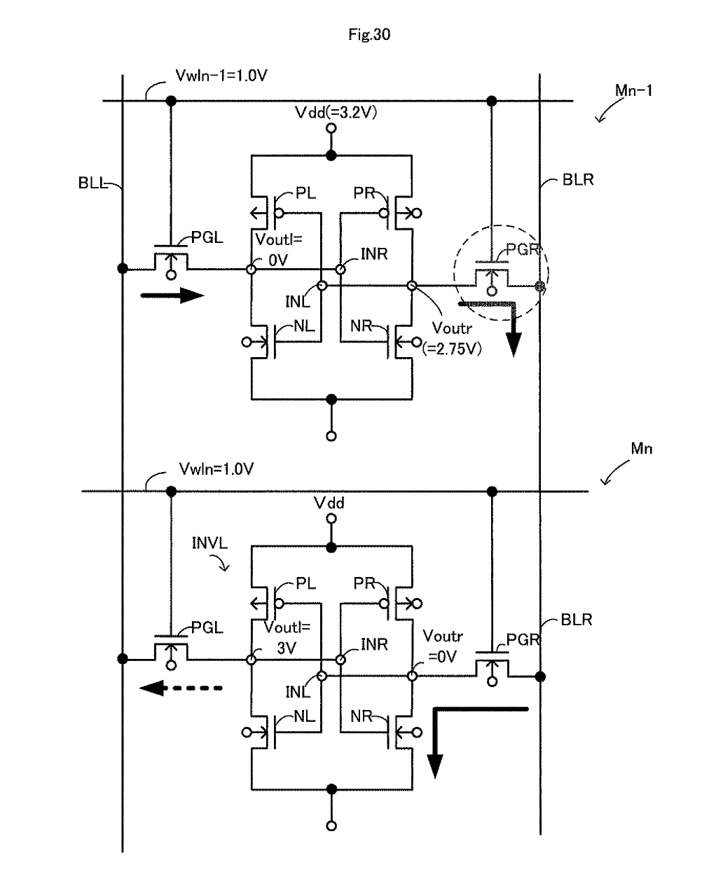

Then, the voltage Vdd is increased to a value V6 (for example 3.2 V) greater than value V1. In this state, a precharge signal PRCHG (value V1) is input into the precharge circuit 422 to turn off the precharge circuit 422, a column signal COL (0 V) is input into the column switches 420 to turn off all the column switches 420, and a voltage having a value V1 is applied to Vw1 of all word lines WL1 to WLn for a predetermined period of time tref (step S220). FIG. 30 illustrates exemplary bias conditions and an exemplary current flowing through the SRAM 410 while the processing at step S220 is being performed. Assumption in the figure is that current balance in memory cell 12n-1 holds data inverted by improper current balance among transistors because of a low threshold voltage of the pass gate transistor PGR and the memory cells (for example memory cell 12n) other than memory cell 12n-1 hold data not inverted by the processing at step S210. That is, the assumption here is that the voltage at the output terminal OUTL of memory cell 12n-1 is lower than the voltage at the output terminal OUTR and the output voltage at the output terminal OUTL of the memory cell 12n is higher than the voltage at the output terminal OUTR. During the processing at step S220, the output terminal OUTR of memory cell 12n-1 is at a voltage (for example 2.73 V) somewhat smaller than the voltage applied to the voltage Vdd whereas the voltage at the output terminal OUTR of each of the memory cells other than memory cell 12n-1 is 0 V and therefore the voltage of the bit line BLR is near 0 V. At this point in time, a voltage having value V1 (for example 1.0 V) is being applied to the gate of the pass gate transistor PGR of memory cell 12n-1, a voltage (for example 2.73 V) somewhat lower than the voltage applied to the voltage Vdd is being applied to the drain, a voltage of 0 V is being applied to the source, and a substrate voltage Vsub of 0 V is being applied to the substrate voltage Vsub. Since these voltage conditions are the same as the voltage conditions illustrated in FIG. 6 except that 0 V is applied to the substrate voltage Vsub, hot electrons are generated near the drain of the pass gate transistor PGR by impact ionization and the generated hot electrons are injected into a region near the drain end of the insulating layer 22. This increases the threshold voltage of the pass gate transistor PGR to a level higher than before the injection of hot electrons and ensures a proper current balance among transistors. In this process, hot electrons can be injected into the pass gate transistors PGR of a plurality of memory cells that have low threshold voltages at the time simply by performing the processing at step S220 once. Thus, the voltage characteristics of the SRAM 410 can be adjusted by a simpler way. The predetermined period of time tref used was determined by experiments and analysis as a period of time that could sufficiently increase the threshold voltages of the pass gate transistors PGR by injection of hot electrons into the insulating layer 22. The voltage applied to the word line WL1 to WLn at this point in time may be any voltage level that enables hot electrons to be sufficiently injected into the insulating layer 22 and may be higher than voltage value V1 and lower than voltage value V6.

During the processing at step S220, the voltage at the output terminal OUTL of memory cell 12n-1 is 0 V whereas the voltage at the output terminals OUTL of the memory cells other than memory cell 12n-1 is slightly smaller (for example 2.73 V) than the voltage applied to the voltage Vdd. Accordingly, when the voltage of the bit line BLL becomes higher than the voltage applied to the word line WL1 to WLn by a value equal to the threshold voltage of the p-channel MOS transistor of the precharge circuit 422, leak current flows through the p-channel MOS transistor of the precharge circuit 422 to precharge the bit line BLL to the supply voltage (value V1) of the peripheral circuitry, which restrains an excessive increase in current flowing through the pass gate transistor PGL of each memory cell 12. Accordingly, an increase in voltage at the output terminal OUTL of the memory cell 12n-1 and a decrease in voltage at the output terminal OUTR are restrained and injection of hot electrons into the pass gate transistor PGR can be continued.

After the completion of step S220, a voltage having value V1 is applied to the voltage Vdd, a voltage of 0 V is applied to each bit line BLL, and a voltage having value V1 is applied to each bit line BLB to perform a data write operation on all of the memory cells 12 of the SRAM 410 (step S230). This operation can force the output terminal OUTL to low and the output terminal OUTR to high in every memory cell 12.

Then, processing at steps S240 and processing at S250, which are the same as steps S210 and S220, are performed in sequence and then the process ends. The processing at step S250 injects hot electrons into the pass gate transistor PGL of a cell that holds data inverted after the processing at step S240 because current balance among transistors is improper due to a low threshold voltage of the pass gate transistor PGL to increase the threshold voltage compared with before the injection. Thus, the voltage characteristics of the SRAM 410 can be adjusted. The injection of hot electrons can be made in the pass gate transistors PGL of a plurality of memory cells having low threshold voltages at the same time simply by performing the processing of at step S250 once. Accordingly, the voltage characteristics of the SRAM 410 can be adjusted in a simpler way.

In the SRAM 410 of the fourth embodiment described above, value VI is applied to the voltage Vdd, value V1 is applied to the bit lines BLL, and 0 V is applied to the bit lines BLR and a data write operation is performed on all of the memory cells 12 of the SRAM 410. After the write operation, value V5 smaller than value V1 is applied to the voltage Vdd and a data read operation is performed on all of the memory cells 12 in sequence. After the read operation, voltage Vdd is increased to value V6 that is greater than. V1, a precharge signal PRCHG (value V1) is input into the precharge circuit 422 to turn off the precharge circuit 422, a column signal COL (0 V) is input into the column switches 420 to turn off all of the column switches 420 and a voltage having value V1 is applied to all of the word lines WL1 to WLn for a predetermined period of time tref. This can inject hot electrons to a plurality of pass gate transistors PGR that have low threshold voltages at once to increase the threshold voltages. Thus, the voltage characteristics of the SRAM 410 can be adjusted in a simplified way. Furthermore, a voltage having value V1 is applied to the voltage Vdd, 0 V is applied to the bit lines ELL, and a voltage having value V1 is applied to the bit lines BLR to perform a data write operation on all of the memory cells 12 of the SRAM 410 and, after the write operation, a voltage having value V5 smaller than value Vi is applied to the voltage Vdd to perform a data read operation on all of the memory cells 12 in sequence, After the read operation, the voltage Vdd is increased to a value V6 greater than value V1, the precharge circuits 422 and the column switches 420 are turned off, and a voltage having value V1 is applied to the voltage Vw1 of all of the word lines WL1 to WLn for a predetermined period of time tref. This can inject hot electrons into a plurality of pas gate transistors PGL that have low threshold voltages at once to increase the threshold voltages. Thus, the voltage characteristics of the SRAM 410 can be adjusted in a simpler way.

While the threshold voltages of the pass gate transistors PGR are adjusted in the processing at steps S200 to S220 and the threshold voltages of the pass gate transistors PGL are adjusted in the processing at steps S230 to S250 in the voltage adjusting method for the SRAM 410 of the fourth embodiment, the threshold voltages of only pass gate transistors PGL or PGR may be adjusted. In that case, when the threshold voltages of pass gate transistors PGR are adjusted, only the processing at steps S200 to S220 needs to be performed without performing steps S230 to S250; when the threshold voltages of pass gate transistors PGL are adjusted, only the processing at steps S230 to S250 needs to be performed without performing steps S200 to S220.

While the processing at steps S200 to S250 is performed for all of the memory cells 12 in the voltage adjusting method for the SRAM 410 of the fourth embodiment, the processing at steps S200 to S250 may be performed on some of the memory cells 12. In that case, current generated when hot electrons are injected into pass gate transistors that have low threshold voltages in the processing at steps S220 and S250 needs to be passed to a ground voltage application point Vss through bit lines BLL, BLR and other pass gate transistors. Therefore the processing at steps S200 to S250 is performed for at least two memory cells 12 connected to the same bit lines BLL, BLR.

The SRAM 410 for which voltage adjustment is performed includes the precharge circuits 422 in the fourth embodiment. The precharge circuits 422 may precharge to a voltage (for example voltage Vdd) higher than supply voltage Vdd1 of the peripheral circuitry, or may clamp to a voltage (for example voltage (vdd1/2)) lower than the supply voltage Vdd1 of the peripheral circuitry, or the precharge circuits 422 may be omitted.

While the voltage characteristics adjusting process of the present invention is applied to circuitry including transistors PL, PR, NL and NR having the structures illustrated in FIGS. 3 and 4 in the fourth embodiment, the voltage characteristics adjusting process may be applied to circuitry in which transistors PL, PR are formed on an n-conductivity-type semiconductor substrate and transistors NL, NR are formed in p-conductivity-type wells formed in an n-type semiconductor substrate.

While each of the memory cells 12 of the SRAM 410 includes an inverter INVL made up of transistors PL and NL and an inverter INVR made up of transistors PR and NR in the fourth embodiment, the inverters INVL and INVR may have any configuration that inverts the logic of a voltage input through the input terminal and outputs the inverted voltage through the output terminal. For example, resistance elements having a relatively high resistivity may be used instead of the transistors PL, PR.

While modes for carrying out the present invention have been described with embodiments, the present invention is not limited to these embodiments. It will be understood that the present invention can be carried out in various modes without departing from the spirit of the present invention.

### INDUSTRIAL APPLICABILITY

The present invention is applicable in the semiconductor memory element manufacturing industry and the charge pump manufacturing industry.

1. A method for adjusting voltage characteristics of a semiconductor memory element formed on a semiconductor substrate, the semiconductor memory element including a first inverter having a first input terminal and a first output terminal, a second inverter having a second input terminal connected to the first output terminal and a second output terminal connected to the first input terminal, a first pass gate transistor having a first gate insulating layer having a predetermined insulation performance, and a second pass gate transistor having a second gate insulating layer having a predetermined insulation performance, a gate of the first pass gate transistor being connected to a word line, one of a source and a drain of the first pass gate transistor being connected to the first output terminal of the first inverter, the other of the source and the drain of the first pass gate transistor being connected to one of two bit lines, a gate of the second pass gate transistor being connected to the word line, one of a source and a drain of the second pass gate transistor being connected to the output terminal of the second inverter, the other of the source and the drain of the second pass gate transistor being connected to the other of the two bit lines, the method comprising:
a voltage adjusting step of adjusting a voltage to be applied to a supply voltage application point and a voltage to be applied to the two bit lines so that a voltage difference between the supply voltage application point to which a supply voltage is to be applied when the semiconductor memory element is caused to perform a normal operation and the two bit lines becomes equal to a predetermined voltage difference greater than a voltage difference between the supply voltage application point and the two bit lines when the semiconductor memory element is caused to perform the normal operation.

2. A method for adjusting voltage characteristics of a semiconductor memory element according to claim 1, the method comprising:
before the voltage adjusting step, a write step of applying a normal-operation on-control voltage to the word line while a first bit voltage out of the first bit voltage and a second bit voltage is being applied to one of the two bit lines and the second bit voltage lower than the first bit voltage is being applied to the other of the two bit lines, the first bit voltage being a voltage to be applied to the bit lines when the semiconductor memory element is caused to perform the normal operation, the normal-operation on-control voltage being a voltage turning on the first pass gate transistor and the second pass gate transistor when the semiconductor memory element is caused to perform the normal operation.

3. A method for adjusting voltage characteristics of a semiconductor memory element according to claim 1, the method comprising:
before the voltage adjusting step, a low supply voltage applying step of applying a predetermined low voltage to the supply voltage application point while a normal-operation off-control voltage is being applied to the word line and a normal-operation substrate voltage is being applied to the semiconductor substrate, the normal-operation off-control voltage being a voltage turning off the first pass gate transistor and the second pass gate transistor when the semiconductor memory element is caused to perform the normal operation, the normal-operation substrate voltage being a voltage to be applied to the semiconductor substrate when the semiconductor memory element is cause to perform the normal operation, the predetermined low voltage being a voltage lower than a supply voltage to be applied to the supply voltage application point when the semiconductor memory element is caused to perform the normal operation.

4. A method for adjusting voltage characteristics of a semiconductor memory element according to claim 3, the method comprising:
between the low supply voltage applying step and the voltage adjusting step, a read step of applying a normal-operation on-control voltage to the word line while the two bit lines are placed in an electrically floating state and the normal-operation substrate voltage is being applied to the semiconductor substrate, the normal-operation on-control voltage being a voltage turning on the first pass gate transistor and the second pass gate transistor when the semiconductor memory element is caused to perform a normal operation.

5. A method for adjusting voltage characteristics of a semiconductor memory element according to claim 4.
wherein the voltage adjusting step is the step of adjusting a voltage to be applied to the supply voltage application point, a voltage to be applied to the word line and a voltage to be applied to the two bit lines so that a voltage difference between the supply voltage application point and the two bit lines becomes equal to the predetermined voltage difference and a voltage difference between the word line and the two bit lines becomes equal to a predetermined low voltage difference smaller than the predetermined voltage difference.

6. A method for adjusting voltage characteristics of a semiconductor memory element according to claim 5,
wherein the voltage adjusting step is the step of applying a normal-operation on-control voltage to the word line, a second bit voltage out of a first bit voltage and the second bit voltage to the two bit lines, a predetermined high supply voltage to the supply voltage application point, the first and second bit voltages are voltages to be applied to the bit lines when the semiconductor memory element is caused to perfoiin the normal operation, the second bit voltage being lower than the first bit voltage, the predetermined high supply voltage being a voltage higher than a supply voltage to be applied to the supply voltage application point when the semiconductor memory element is caused to perform the normal operation and higher than the normal-operation on-control voltage.

7. A method for adjusting voltage characteristics of a semiconductor memory element according to claim 6,
wherein the voltage adjusting step is the step of applying the normal operation on-control voltage to the word line, the second bit voltage to the two bit lines, and the predetermined high supply voltage to the supply voltage application point in a state where a voltage to be applied to the semiconductor substrate has been adjusted so that a voltage applied to the semiconductor substrate is lower than a normal substrate voltage to be applied to the semiconductor substrate when the semiconductor memory device is caused to perform the normal operation.

8. A method for adjusting voltage characteristics of a semiconductor memory element according to claim 1.
wherein the voltage adjusting step is the step of adjusting a voltage to be applied to the supply voltage application point and a voltage to be applied to the two bit lines so that a voltage difference between the supply voltage application point and the two bit lines becomes equal to the predetermined voltage difference and a voltage difference between the word line and the two bit lines becomes equal to a predetermined high voltage difference greater than the predetermined voltage difference.

9. A method for adjusting voltage characteristics of a semiconductor memory element according to claim 8,
wherein the voltage adjusting step is the step of applying a predetermined off voltage to the word line, applying a predetermined high bit voltage to the two bit lines, and applying a predetermined low supply voltage to the supply voltage application point, the predetermined off-voltage being lower than a normal-operation off-control voltage turning off the first pass gate transistor and the second pass gate transistor when the semiconductor memory element is caused to perform the normal operation, the predetermined high bit voltage being a higher than a first bit voltage out of the first bit voltage and a second bit voltage to be applied to the bit lines when the semiconductor memory element is caused to perform the normal operation, the second bit voltage being lower than the first bit voltage, the predetermined low supply voltage being lower than a supply voltage to be applied to the supply voltage application point when the semiconductor memory element is caused to perform the normal operation.

10. A charge pump comprising a multi-stage transistor circuit, a capacitor circuit, an input signal supply circuit, and a control circuit, the multi-stage transistor circuit having a first input terminal, a second input terminal, a third input terminal, and an output terminal and including n transistors connected in series (n is an integer greater than or equal to 2), each of the n transistors having a connection terminal, a gate of each of the n transistors being formed on an insulating layer having a predetermined insulation performance, one of a source and a drain of each of the transistors and the gate being connected to the connection terminal, the source of each of the transistors being connected to the connection terminal of an adjacent transistor, the connection terminal of the transistor at the first stage among the n transistors being connected to the first input terminal, the source of the transistor at the last stage among the n transistors being connected to the output terminal, the capacitor circuit including (n−1) capacitors, one end of each of the capacitors being connected to the connection terminal of (n−1) transistors among the n transistors of the multi-stage transistor circuit excluding the transistor at the first stage, the other end of each of adjacent capacitors that is different from the one end being alternately connected to the second input terminal or the third terminal, the input signal supply circuit being capable of supplying a voltage or a clock signal to the first input terminal, the second input terminal and the third input terminal, the control circuit controlling the input signal supply circuit so that the clock signal is input into the second input terminal and an inverted clock signal that is the inverse of the clock signal is input into the third input terminal while a supply voltage is being supplied to the first input terminal when the charge pump is in a normal operation, the charge pump comprising:
a control voltage supply circuit having n control terminals and supplying a voltage to each of the control terminals; and
n switching elements turning on and off supply of a voltage from the n control terminals to the connection terminals and gates of n transistors of the multi-stage transistor circuit;
wherein the control circuit controls the input signal supply circuit, the control voltage supply circuit, and the n switching elements so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching in the on state and a predetermined high voltage higher than the predetermined low voltage is applied to the other of the control terminals connected to the two switching elements in the on state.

11. A charge pump according to claim 10,
wherein the control circuit controls the input signal supply circuit, the n switching elements and the control voltage supply circuit so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching elements in the on state that is nearer to the transistor at the first stage of the multi-stage transistor circuit and a predetermined high voltage higher than the predetermined low voltage is applied to the other of the control terminals connected to the two switching elements in the on state that is nearer to the transistor at the last stage of the multi-stage transistor circuit.

12. A charge pump according to claim 10,
wherein the control circuit controls the input signal supply circuit, the n switching elements and the control voltage supply circuit so that, while a predetermined low voltage is being input in the first input terminal, the second input terminal and the third input terminal and adjacent two of the n switching elements are in the on state and the other switching elements are in the off state, a predetermined high voltage higher than the predetermined low voltage is applied to one of the control terminals connected to the two switching elements in the on state that is nearer to the transistor at the first stage of the multi-stage transistor circuit and a voltage lower than or equal to the predetermined low voltage is applied to the other of the two control terminals connected to the two switching elements in the on state that is nearer to the last stage of the multi-state transistor circuit.

13. A voltage characteristics adjusting method for adjusting voltage characteristics of a charge pump including a multi-stage transistor circuit, a capacitor circuit, an input signal supply circuit, a control voltage supply circuit and n switching elements, the multi-stage transistor circuit having a first input terminal, a second input terminal, a third input terminal, and an output terminal and including n transistors connected in series (n is an integer greater than or equal to 2), each of the n transistors having a connection terminal, a gate of each of the n transistors being formed on an insulating layer having a predetermined insulation performance, one of a source and a drain of each of the transistors and the gate being connected to the connection terminal, the source of each of the transistors being connected to the connection terminal of an adjacent transistor, the connection terminal of the transistor at the first stage among the n transistors being connected to the first input terminal, the source of the transistor at the last stage among the n transistors being connected to the output terminal, the capacitor circuit includes (n−1) capacitors, one end of each of the capacitors being connected to the connection terminal of (n−1) transistors among the n transistors of the multi-stage transistor circuit excluding the transistor at the first stage, the other end of each of adjacent capacitors that is different from the one end being alternately connected to the second input terminal or the third terminal, the input signal supply circuit being capable of supplying a voltage or a clock signal to the first input terminal, the second input terminal and the third input terminal, the control voltage supply circuit having n control terminals and supplying a voltage to each of the control terminals, the n switching elements turning on and off supply of a voltage from the n control terminals to the connection terminals and the gate of the n transistors of the multi-stage transistor circuit, the charge pump controls the input signal supply circuit and the n switching elements so that the clock signal is input into the second input terminal and an inverted clock signal that is the inverse of the clock signal is input into the third input terminal while the n switching elements are turned off and a supply voltage is being supplied to the first input terminal when the charge pump is in a normal operation,
wherein the method controls the input signal supply circuit, the control voltage supply circuit and the n switching elements so that, while a predetermined low voltage is being input in the first input terminal, the second input terminal and the third input terminal and adjacent two of the n switching elements are in the on state and the other switching elements are in the off state, a voltage lower than or equal to the predetermined low voltage is applied to one of the control terminals connected to the two switching in the on state and a predetermined high voltage higher than the predetermined low voltage is applied to the other of the control terminals connected to the two switching elements in the on state.

14. A method for adjusting voltage characteristics of a semiconductor memory device including n semiconductor memory elements (n is an integer greater than or equal to 2) each including a first inverter having a first input terminal and a first output terminal, a second inverter having a second input terminal connected to the first output terminal and a second output terminal connected to the first input terminal, a first pass gate transistor having a first gate insulating layer having a predetermining insulating performance, and a second pass gate transistor having a second gate insulating layer having a predetermined insulating performance, n word lines connected to the gate of the first pass gate transistor and the gate of the second pass gate transistor of each of the n semiconductor memory elements, a first bit line connected to one of the source and the drain of the first pass gate transistor, and a second bit line connected to one of the source and the drain of the second pass gate transistor, the other of the source and drain of the first pass gate transistor being connected to the first output terminal of the first inverter, the other of the source and the drain of the second pass gate transistor being connected to the output terminal of the second inverter, the method comprising:
a first step of performing a write operation on at least two of the n semiconductor memory elements, the write operation adjusting a voltage to be applied to a supply voltage application point of each of the semiconductor memory element, a voltage to be applied to the first bit line, a voltage to be applied to the second bit line, and a voltage to be applied to the word line, so that a voltage difference between the supply voltage application point to which a supply voltage is to be applied when the semiconductor memory element is cause to perform a normal operation and a word line connected to the first pass gate transistor and the second pass gate transistor of the semiconductor memory element and a voltage difference between the first bit line and the second bit line become equal to a voltage difference between the supply voltage application point and the word line and a voltage difference between the two bit lines when data is normally written into the semiconductor memory element;
after the first step, a second step of performing a low supply voltage read operation on the at least two semiconductor memory elements, the low supply voltage read operation adjusting a voltage to be applied to the supply voltage application point of the semiconductor memory element and a voltage to be applied to the word line so that a normal on voltage which is a voltage turning on the first pass gate transistor and the second pass gate transistor of the semiconductor memory element is applied to the word line while a voltage lower than a normal supply voltage which is a voltage to be applied to the supply voltage application point when the semiconductor memory element is caused to perform a normal operation is being applied to the supply voltage application point; and
after the second step, a third step of adjusting a voltage to be applied to the supply voltage application point of each of the at least two semiconductor memory elements and a voltage to be applied to a word line connected to the at least two semiconductor memory elements so that a voltage higher than or equal to the normal on voltage and lower than the normal supply voltage is applied to the word line connected to the first pass gate transistor and the second pass gate transistor of the at least two semiconductor memory elements while a voltage higher than the normal supply voltage is being applied to the supply voltage application point of each of the at least two semiconductor memory elements.

15. A method for adjusting voltage characteristics of a semiconductor memory device according to claim 14,
wherein the write operation of the first step is the operation of adjusting a voltage to be applied to the supply voltage application point of the semiconductor memory element, a voltage to be applied to the first bit line, and a voltage to be applied to the second bit line so that a first bit voltage which is a voltage to be applied to the bit line when the semiconductor memory element is caused to perform a normal operation out of the first bit voltage and a second bit voltage lower than the first bit voltage is applied to one of the first and second bit lines and the second bit voltage to the other of the first and second bit lines while the normal supply voltage is being applied to the supply voltage application point and the normal on voltage is being applied to the word line.

16. A method for adjusting voltage characteristics of a semiconductor memory device according to claim 15, the method comprising:
after the third step, a fourth step of performing an after-third-step write operation on at least two of the n semiconductor memory elements, the after-third-step write operation adjusting a voltage to be applied to the supply voltage application point of each of the semiconductor memory elements, a voltage to be applied to the first bit line, a voltage to be applied to the second bit line, and a voltage to be applied to the word so that the first bit voltage is applied to the other of the first and second bit lines and the second bit voltage is applied to one of the first and second bit lines while the normal supply voltage is being applied to the supply voltage application point and the normal on voltage is being applied to the word line,
wherein the second step and the third step are performed after the fourth step.

17. A method for adjusting voltage characteristics of a semiconductor memory device according to claim 16,
wherein the first step is the step of performing the write operation on the n semiconductor memory elements;
the second step is the step of performing the low voltage read operation on the n semiconductor memory elements;
the third step is the step of adjusting a voltage to be applied to the supply voltage application point of each of the n semiconductor memory elements and a voltage to be applied to the n word lines so that a voltage higher than or equal to the normal on voltage and the lower than the normal supply voltage is applied to the n word lines while a voltage higher than the normal supply voltage is being applied to the supply voltage application point of each of the n semiconductor memory elements; and
the fourth step is the step of performing the after-third-step write operation on the n semiconductor memory elements.
